(19) United States
(12) Patent Application Publication
(10) Pub. No.: US 2026/0013287 A1
(43) Pub. Date: Jan. 8, 2026

(54) MICROFLUIDIC TRANSFER SUBSTRATE AND METHOD FOR TRANSFERRING LIGHT-EMITTING ELEMENTS

(71) Applicant: HKC CORPORATION LIMITED, SHENZHEN (CN)

(72) Inventors: Zeyao LI, SHENZHEN (CN); Pei XU, SHENZHEN (CN)

(73) Assignee: HKC CORPORATION LIMITED, SHENZHEN (CN)

(21) Appl. No.: 19/248,553

(22) Filed: Jun. 25, 2025

(30) Foreign Application Priority Data
Jul. 2, 2024 (CN) 202410876332.X

(51) Int. Cl. H10H 29/03; H10H 29/01

(52) U.S. Cl. CPC H10H 29/03; H10H 29/012

(57) ABSTRACT

A microfluidic transfer substrate includes a plurality of pixel groups. Each pixel group includes at least three first pixel units, and the at least three first pixel units of each pixel group are arranged around a center point; and one first pixel unit of each pixel group serves as a first microfluidic pixel and a surface of the first microfluidic pixel defines an assembly groove, and the other first pixel units of each pixel group serve as second microfluidic pixels and a surface of each second microfluidic pixel is free of the assembly groove. Two adjacent pixel groups share at least one second microfluidic pixel. A method for transferring light-emitting elements is further provided.

### CROSS-REFERENCE TO RELATED APPLICATIONS

The present application claims priority to Chinese Patent Application No. 202410876332.X, entitled “MICROFLUIDIC TRANSFER SUBSTRATE AND METHOD FOR TRANSFERRING LIGHT-EMITTING ELEMENTS”, filed on Jul. 2, 2024, which is herein incorporated by reference in its entirety.

### TECHNICAL FIELD

The present disclosure relates to the field of display technologies, and in particular to a microfluidic transfer substrate and a method for transferring light-emitting elements.

### BACKGROUND

With the advancement of light-emitting diode (LED) technology, micro-LED display technology is emerging as a revolutionary next-generation technology. The micro-LED is a display technology that miniaturizes and matrixes traditional LED structures, and achieves address control and individual driving of each pixel point through a driving backplane. Due to its superior performance in brightness, lifespan, contrast, response time, and other indicators compared to a liquid crystal display (LCD) and an organic light-emitting diode display (OLED), the micro-LED has been regarded by many manufacturers as the next-generation display technology, and the manufacturers have begun to actively layout the micro-LED.

However, a core technical challenge in the industrialization of the micro-LED is the mass transfer technology of micro-LED components. In related art, there is a problem of low pixel density during transferring micro-LED components to the driver backplane.

### SUMMARY OF THE DISCLOSURE

A technical solution in the present disclosure is to provide a microfluidic transfer substrate. The microfluidic transfer substrate includes a plurality of pixel groups. Each pixel group includes at least three first pixel units, and the at least three first pixel units of each pixel group are arranged around a center point; and one first pixel unit of each pixel group serves as a first microfluidic pixel and a surface of the first microfluidic pixel defines an assembly groove, and the other first pixel units of each pixel group serve as second microfluidic pixels and a surface of each second microfluidic pixel is free of the assembly groove. Two adjacent pixel groups share at least one second microfluidic pixel.

In some embodiments, the plurality of pixel groups are arranged in a two-dimensional array; each pixel group includes four first pixel units, and the four first pixel units of the same pixel group are arranged to form a two-dimensional array with two rows and two columns; and two adjacent pixel groups in the same row share two second microfluidic pixels.

In some embodiments, two adjacent pixel groups in the same row share two second microfluidic pixels, and two adjacent pixel groups in the same column share two second microfluidic pixels.

In some embodiments, nine first pixel units arranged in three rows and three columns form a repeating unit, four first pixel units located at four corners of each repeating unit are the first microfluidic pixels, and the other five first pixel units are the second microfluidic pixels.

In some embodiments, each first pixel unit includes a substrate, a thin film transistor, a first insulation layer, a planarization layer, a microfluidic electrode layer, a second insulation layer, and a hydrophobic layer arranged in sequence; and the planarization layer defines a through hole to expose a part of the first insulation layer, so that the assembly groove is formed. The microfluidic electrode layer, the second insulation layer, and the hydrophobic layer all cover a bottom surface and a side surface of the assembly groove; or, the microfluidic electrode layer is only disposed on a surface of the planarization layer away from the substrate and defines an opening corresponding to the assembly groove, and the second insulation layer and the hydrophobic layer both cover the bottom surface and the side surface of the assembly groove.

In some embodiments, the microfluidic transfer substrate includes a transfer area and a liquid droplet generation area surrounding the transfer area; the plurality of pixel groups are disposed in the transfer area, and the liquid droplet generation area is configured to generate and transport a liquid droplet containing a light-emitting element to the transfer area, and a plurality of second pixel units are disposed in the liquid droplet generation area, and a structure of each second pixel unit is the same as that of each second microfluidic pixel.

Another technical solution in the present disclosure is to provide a method for transferring light-emitting elements, and the method includes the following operations:
providing a microfluidic transfer substrate of any one of above embodiments;
forming a liquid droplet containing a light-emitting element in an area where each pixel group of the microfluidic transfer substrate is located, wherein at most one of two liquid droplets containing the light-emitting elements in areas where two adjacent pixel groups are located is located on the shared second microfluidic pixel;
driving the two liquid droplets containing the light-emitting elements in the areas where the two adjacent pixel groups are located in a time-sequenced manner, so that the two liquid droplets containing the light-emitting elements rotate around the center points at different time periods, so as to assemble the light-emitting elements into the assembly grooves; and
attaching the microfluidic transfer substrate to a driving backplane, so that the light-emitting elements in the assembly grooves are transferred to the driving backplane.

In some embodiments, the driving the two liquid droplets containing the light-emitting elements in the areas where the two adjacent pixel groups are located in a time-sequenced manner, includes:
simultaneously driving the liquid droplets containing the light-emitting elements in areas where odd-numbered columns of pixel groups are located in a first time period, so that the liquid droplets containing the light-emitting elements rotate around the center points, so as to assemble the light-emitting elements into the assembly grooves; and
simultaneously driving the liquid droplets containing the light-emitting elements in areas where even-numbered columns of pixel groups are located in a second time period, so that the liquid droplets containing the light-emitting elements rotate around the center points, so as to assemble the light-emitting elements into the assembly grooves;
wherein the first time period and the second time period are different time periods.

In some embodiments, the driving the two liquid droplets containing the light-emitting elements in the areas where the two adjacent pixel groups are located in a time-sequenced manner, includes:
simultaneously driving the liquid droplets containing the light-emitting elements in areas where the pixel groups in odd-numbered columns and odd-numbered rows are located in a first time period, so that the liquid droplets containing the light-emitting elements rotate around the center points, so as to assemble the light-emitting elements into the assembly grooves;
simultaneously driving the liquid droplets containing the light-emitting elements in areas where the pixel groups in the odd-numbered columns and even-numbered rows are located in a second time period, so that the liquid droplets containing the light-emitting elements rotate around the center points, so as to assemble the light-emitting elements into the assembly grooves;
simultaneously driving the liquid droplets containing the light-emitting elements in areas where the pixel groups in even-numbered columns and the odd-numbered rows are located in a third time period, so that the liquid droplets containing the light-emitting elements rotate around the center points, so as to assemble the light-emitting elements into the assembly grooves; and
simultaneously driving the liquid droplets containing the light-emitting elements in areas where the pixel groups in the even-numbered columns and the even-numbered rows are located in a fourth time period, so that the liquid droplets containing the light-emitting elements rotate around the center points, so as to assemble the light-emitting elements into the assembly grooves;
wherein the first time period, the second time period, the third time period, and the fourth time period are different time periods.

Yet another technical solution in the present disclosure is to provide a method for transferring light-emitting elements, and the method including:
providing a microfluidic transfer substrate of any one of above embodiments;
transporting the liquid droplets containing the light-emitting elements to an area where a first group of pixel groups is located, and driving the liquid droplets containing the light-emitting elements to rotate around the center points, so as to assemble the light-emitting elements into the assembly grooves in a first time period; wherein adjacent pixel groups in the first group of pixel groups do not share the second microfluidic pixel;
transporting the liquid droplets containing the light-emitting elements to an area where a second group of pixel groups is located, and driving the liquid droplets containing the light-emitting element to rotate around the center points, so as to assemble the light-emitting elements into the assembly grooves in a second time period; wherein adjacent pixel groups in the second group of pixel groups do not share the second microfluidic pixel; the pixel groups in the second group of pixel groups correspond one-to-one with the pixel groups in the first group of pixel groups, the pixel groups in the second group of pixel groups are adjacent to the pixel groups in the first group of pixel groups, and the pixel groups in the second group of pixel groups and the pixel groups in the first group of pixel groups share at least one second microfluidic pixel; and the first time period and the second time period are different time periods; and
attaching the microfluidic transfer substrate to a driving backplane, so that the light-emitting elements in the assembly grooves are transferred to the driving backplane.

### BRIEF DESCRIPTION OF THE DRAWINGS

In order to more clearly illustrate the technical solutions in some embodiments of the present disclosure or in the related art, hereinafter, the accompanying drawings that are used in the description of some embodiments or the related art will be briefly described. Obviously, the accompanying drawings in the description below are merely the accompanying drawings in some embodiments of the present disclosure. For those of ordinary skill in the art, other accompanying drawings may be obtained based on these accompanying drawings without any creative efforts.

FIG. 1 is a structural schematic view of an embodiment of a microfluidic transfer substrate in the present disclosure.

FIG. 2 is a structural schematic view illustrating two adjacent pixel groups of the microfluidic transfer substrate of FIG. 1.

FIG. 3 is a cross-sectional structural schematic view of the microfluidic transfer substrate of FIG. 1.

FIG. 4 is a structural schematic view illustrating two adjacent pixel groups in another embodiment of the microfluidic transfer substrate in the present disclosure.

FIG. 5 is a structural schematic view illustrating two adjacent pixel groups in yet another embodiment of the microfluidic transfer substrate in the present disclosure.

FIG. 6 is a structural schematic view of another embodiment of the microfluidic transfer substrate in the present disclosure.

FIG. 7 is an enlarged schematic view of an area A of FIG. 6.

FIG. 8 is a flowchart of a first embodiment of a method for transferring light-emitting elements in the present disclosure.

FIG. 9 is a structural schematic view corresponding to an embodiment of an operation at block S2 of FIG. 8.

FIG. 10 is a flowchart of an embodiment of an operation at block S3 of FIG. 8.

FIG. 11 is a structural schematic view corresponding to an operation at block S31A of FIG. 10.

FIG. 12 is a structural schematic view corresponding to an operation at block S32A of FIG. 10.

FIG. 13 is a flowchart of another embodiment of the operation at block S3 of FIG. 8.

FIG. 14 is a structural schematic view corresponding to an operation at block S31B of FIG. 13.

FIG. 15 is a structural schematic view corresponding to an operation at block S32B of FIG. 13.

FIG. 16 is a structural schematic view corresponding to an operation at block S33B of FIG. 13.

FIG. 17 is a structural schematic view corresponding to an operation at block S34B of FIG. 13.

FIG. 18 is a cross-sectional structural schematic view of a structure of FIG. 12.

FIG. 19 is a structural schematic view corresponding to an operation at block S4 of FIG. 8.

FIG. 20 is a flowchart of a second embodiment of the method for transferring light-emitting elements in the present disclosure.

FIG. 21 is a structural block view of a microfluidic transfer device in the present disclosure.

FIG. 22 is a structural block view of a microfluidic transfer apparatus in the present disclosure.

### DETAILED DESCRIPTION

The technical solutions in some embodiments of the present disclosure may be clearly and completely described in conjunction with accompanying drawings in some embodiments of the present disclosure. Obviously, the described embodiments are only a part of the embodiments of the present disclosure, and not all embodiments. Based on the embodiments in the present disclosure, all other embodiments obtained by those of ordinary skill in the art without creative effort are within the scope of the present disclosure.

The terms “first”, “second”, and “third” in the present disclosure are only configured to describe and cannot be understood as indicating or implying relative importance or implicitly indicating the quantity of technical features indicated. Therefore, features that are defined as “first”, “second”, and “third” may explicitly or implicitly include at least one of these features. In the description of the present disclosure, “multiple” means at least two, such as two, three, etc., unless otherwise expressly and specifically qualified. In addition, the terms “including”, “comprising”, and “having”, as well as any variations of the terms “including”, “comprising”, and “having”, are intended to cover non-exclusive inclusions. For example, a process, method, system, product, or apparatus that includes a series of operations or units is not limited to the listed operations or units, but optionally includes operations or units that are not listed, or optionally includes other operations or units that are inherent to these processes, methods, products, or apparatus.

The reference to “embodiment” in the present disclosure means that, specific features, structures, or characteristics described in conjunction with some embodiments may be included in at least one embodiment of the present disclosure. The phrase appearing in various positions in the specification does not necessarily refer to the same embodiment, nor is it an independent or alternative embodiment that is mutually exclusive with other embodiments. Those of ordinary skill in the art explicitly and implicitly understand that the embodiments described in the present disclosure can be combined with other embodiments.

The present disclosure mainly provides a microfluidic transfer substrate and a method for transferring light-emitting elements, so as to solve the problem of low pixel density during transferring the light-emitting elements to a driving backplane in related art.

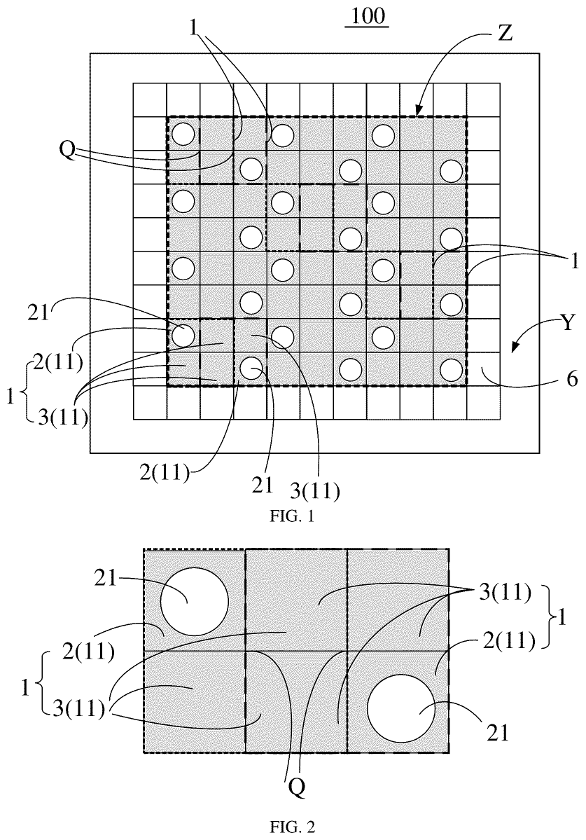

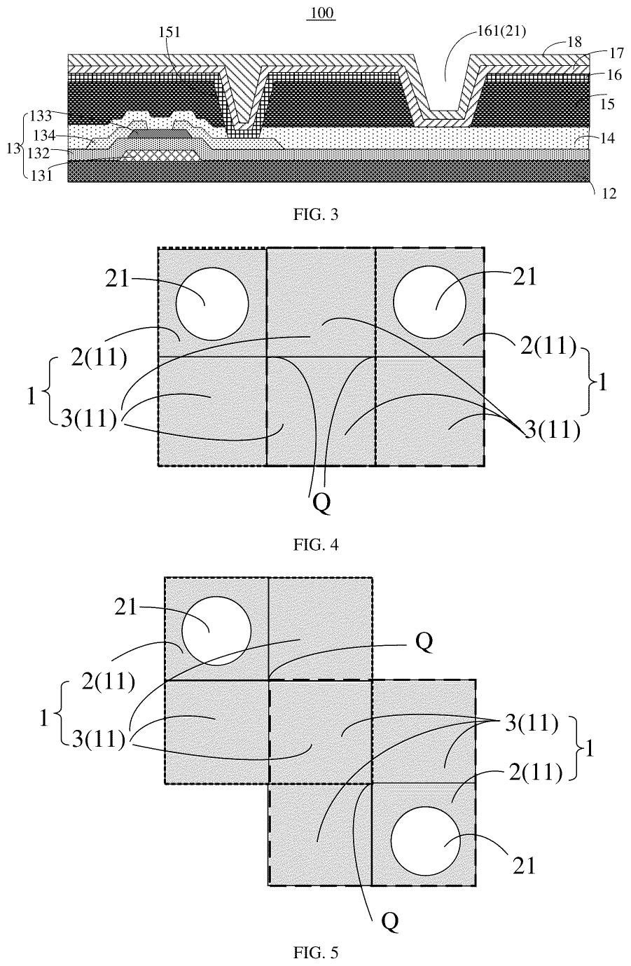

As illustrated in FIGS. 1 to 5, FIG. 1 is a structural schematic view of an embodiment of a microfluidic transfer substrate in the present disclosure. FIG. 2 is a structural schematic view illustrating two adjacent pixel groups of the microfluidic transfer substrate of FIG. 1. FIG. 3 is a cross-sectional structural schematic view of the microfluidic transfer substrate of FIG. 1. FIG. 4 is a structural schematic view illustrating two adjacent pixel groups in another embodiment of the microfluidic transfer substrate in the present disclosure. FIG. 5 is a structural schematic view illustrating two adjacent pixel groups in yet another embodiment of the microfluidic transfer substrate in the present disclosure.

As illustrated in FIG. 1, the present disclosure provides a microfluidic transfer substrate 100, and the microfluidic transfer substrate 100 may be configured for mass transfer of light-emitting elements 4. In some embodiments, the microfluidic transfer substrate 100 includes multiple pixel groups 1, each pixel group includes at least three first pixel units 11. The first pixel units 11 of each pixel group 1 are arranged around a center point Q. One first pixel unit 11 of each pixel group 1 serves as a first microfluidic pixel 2, and a surface of the first microfluidic pixel 2 defines an assembly groove 21. The other first pixel units 11 of each pixel group 1 serve as second microfluidic pixels 3, and a surface of each of the second microfluidic pixels 3 does not define the assembly groove 21. Two adjacent pixel groups 1 share at least one second microfluidic pixel 3.

Each pixel group 1 of the microfluidic transfer substrate 100 is set to include at least three first pixel units 11, and the multiple first pixel units 11 of the pixel group 1 are arranged around the center point Q. One first pixel unit 11 of each pixel group 1 serves as the first microfluidic pixel 2, and the surface of the first microfluidic pixel 2 defines the assembly groove 21. It may facilitate assembly of the light-emitting element 4 into the assembly groove 21 of the first microfluidic pixel 2 by using the microfluidic transfer substrate 100, and then the light-emitting element 4 assembled on the microfluidic transfer substrate 100 is transferred to the driving backplane 700, which is conducive to achieving mass transfer of the light-emitting elements 4. The distribution of the first pixel units 11 of the pixel group 1 also makes it easier to assemble the light-emitting element 4 into the assembly groove 21 during assembling the light-emitting element 4 on the microfluidic transfer substrate 100, thereby improving assembly efficiency. Furthermore, two adjacent pixel groups 1 share at least one second microfluidic pixel 3, which may effectively increase the pixel density of the first microfluidic pixels 2 on the microfluidic transfer substrate 100, increase the assembly density of the light-emitting elements 4, thereby improving the light-emitting efficiency of the light-emitting elements 4 transferred to the driving backplane 700.

As illustrated in FIGS. 1 to 4, in some embodiments, the multiple pixel groups 1 of the microfluidic transfer substrate 100 are arranged in a two-dimensional array. Each pixel group 1 includes four first pixel units 11, and the four first pixel units 11 of the same pixel group 1 are arranged to form a two-dimensional array of two rows and two columns. Two adjacent pixel groups 1 in the same row share two second microfluidic pixels 3. In some embodiments, the first pixel unit 11 is rectangular. That is, the four first pixel units 11 in each pixel group 1 of the microfluidic transfer substrate 100 form the two-dimensional array of two rows and two columns. In each pixel group 1, one first pixel unit 11 serves as the first microfluidic pixel 2 defining the assembly groove 21, and the other three first pixel units 11 serve as the second microfluidic pixels 3.

Two adjacent pixel groups 1 in the same row are composed of a total of six first pixel units 11, including two first microfluidic pixels 2 and four second microfluidic pixels 3. Each of these two first microfluidic pixels 2 is in one pixel group 1, that is, each pixel group 1 has one first microfluidic pixel 2. Two of the four second microfluidic pixels 3 are shared by the two adjacent pixel groups 1, and each of the other two of the four second microfluidic pixels 3 is in one pixel group 1. That is, each of the two adjacent pixel groups 1 has two second microfluidic pixels 3, and the two adjacent pixel groups 1 share the other two second microfluidic pixels 3.

In some embodiments, as illustrated in FIGS. 2 and 4, the six first pixel units 11 of two adjacent pixel groups 1 in the same row form a two-dimensional array of two rows and three columns. The two adjacent pixel groups 1 share two first pixel units 11 in a middle column (i.e., a second column), and the two first pixel units 11 in the middle column are the second microfluidic pixels 3.

In some embodiments, as illustrated in FIG. 2, in the two-dimensional array of two rows and three columns that is formed by the two adjacent pixel groups 1 in the same row, the first microfluidic pixel 2 of a first pixel group 1 (i.e., the left pixel group 1) is located in the first row and first column, and the first microfluidic pixel 2 of a second pixel group 1 (i.e., the right pixel group 1) is located in the second row and third column. That is, the first microfluidic pixel 2 of the first pixel group 1 is located in the first row and first column of the two-dimensional array that is formed by the four first pixel units 11 of the first pixel group 1. The first microfluidic pixel 2 of the second pixel group 1 is located in the second row and second column of the two-dimensional array that is formed by the four first pixel units 11 of the second pixel group 1. That is, the first microfluidic pixels 2 of the two adjacent pixel groups 1 in the same row belong to the first pixel units 11 of different rows and different columns in their pixel groups 1.

As illustrated in FIG. 4, in some embodiments, in the two-dimensional array of two rows and three columns that is formed by the two adjacent pixel groups 1 in the same row, the first microfluidic pixel 2 of the first pixel group 1 (i.e., the left pixel group 1) is located in the first row and first column, and the first microfluidic pixel 2 of the second pixel group 1 (i.e., the right pixel group 1) is located in the first row and third column. That is, the first microfluidic pixel 2 of the first pixel group 1 is located in the first row and first column of the two-dimensional array that is formed by the four first pixel units 11 of the first pixel group 1. The first microfluidic control pixel 2 of the second pixel group 1 is located in the first row and second column of the two-dimensional array that is formed by the four first pixel units 11 of the second pixel group 1. That is, the first microfluidic pixels 2 of the two adjacent pixel groups 1 in the same row belong to the first pixel units 11 of the same row but different columns in their pixel groups 1.

In some embodiments, each pixel group 1 may also include other numbers of first pixel units 11, and the multiple first pixel units 11 of the same pixel group 1 may not be distributed in an array. In some embodiments, the multiple first pixel units 11 of the same pixel group 1 may be randomly distributed. The multiple pixel groups 1 of the microfluidic transfer substrate 100 may not be distributed in the two-dimensional array. In some embodiments, the multiple pixel groups 1 of the microfluidic transfer substrate 100 may be distributed in any shape or form, as long as the two adjacent pixel groups 1 share at least one second microfluidic pixel 3 to increase pixel density. The first pixel unit 11 may also have any shape, such as a circle, a diamond, a triangle, a pentagon, a hexagon, etc., which may be designed as needed and may not be limited in the present disclosure.

As illustrated in FIG. 5, in some embodiments, the microfluidic transfer substrate 100 includes multiple pixel groups 1, each pixel group 1 includes four first pixel units 11. The four first pixel units 11 of the same pixel group 1 are arranged to form the two-dimensional array of two rows and two columns. The four first pixel units 11 of each pixel group 1 are arranged around the center point Q. One first pixel unit 11 of each pixel group 1 serves as the first microfluidic pixel 2, and the surface of the first microfluidic pixel 2 defines the assembly groove 21. The other three first pixel units 11 serve as the second microfluidic pixels 3, and the surface of each second microfluidic pixel 3 does not define the assembly groove 21. The multiple pixel groups 1 of the microfluidic transfer substrate 100 are not arranged in an array, but every two adjacent pixel groups 1 share one second microfluidic pixel 3.

As illustrated in FIG. 5, the four first pixel units 11 of each pixel group 1 are arranged to form the two-dimensional array of two rows and two columns. There are a total of seven first pixel units 11 in the two adjacent pixel groups 1, and the seven first pixel units 11 are distributed in three rows and three columns, respectively. The first microfluidic pixel 2 of the first pixel group 1 (i.e. the left pixel group 1) is located in the first row and first column of the two-dimensional array of two rows and two columns that is formed by the four first pixel units 11 of the first pixel group 1. The first microfluidic pixel 2 of the second pixel group 1 (i.e. the right pixel group 1) is located in the second row and second column of the two-dimensional array of two rows and two columns that is formed by the four first pixel units 11 of the second pixel group 1. The second microfluidic pixel 3 in the second row and second column of the first pixel group 1 is shared with the second microfluidic pixel 3 in the first row and first column of second pixel group 1. In the three rows and three columns formed by the seven first pixel units 11 that are distributed in two adjacent pixel groups 1, the third row and first column is not provided with the first pixel unit 11, and the first row and third column is not provided with the first pixel unit 11. By allowing the two adjacent pixel groups 1 to share one second microfluidic pixel 3, the pixel density may be effectively increased.

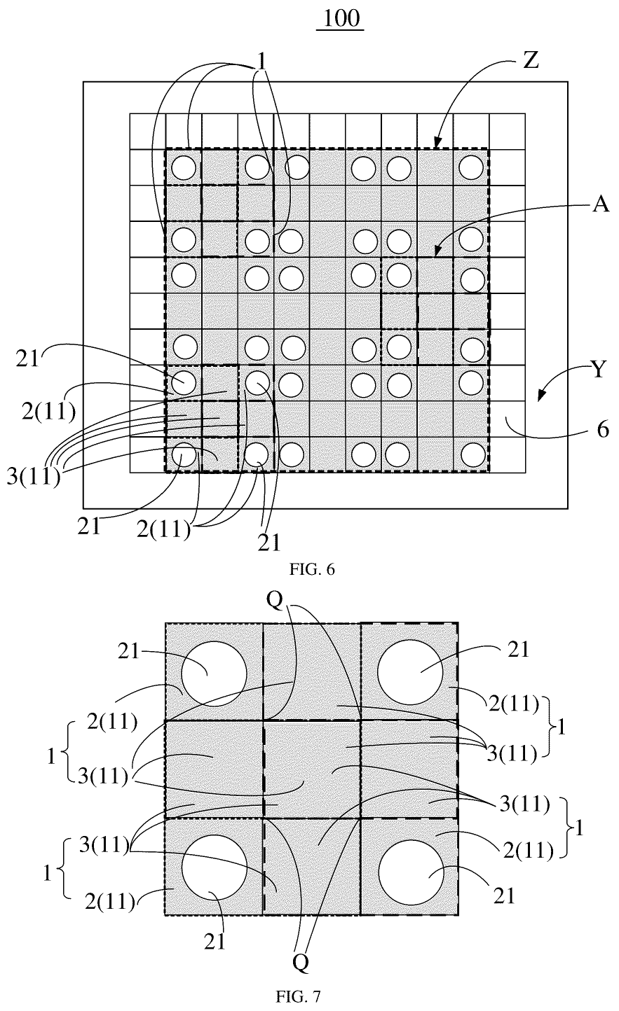

As illustrated in FIGS. 6 and 7, FIG. 6 is a structural schematic view of another embodiment of the microfluidic transfer substrate in the present disclosure, and FIG. 7 is an enlarged schematic view of an area A of FIG. 6.

As illustrated in FIGS. 6 and 7, the present disclosure further provides another microfluidic transfer substrate 100. In some embodiments, in the microfluidic transfer substrate 100, three rows and three columns formed by nine first pixel units 11 forms a repeating unit (as illustrated in FIG. 7). The four first pixel units 11 located at the four corners of each repeating unit are the first microfluidic pixels 2, and the other five first pixel units 11 are the second microfluidic pixels 3. This may further increase the density of the first microfluidic pixels 2 of the multiple pixel groups 1, thereby increasing the assembly density of the light-emitting elements 4 assembled into the assembly grooves 21 of the first microfluidic pixels 2 of the pixel group 1, improving the transfer efficiency of the light-emitting elements 4, and improving the light-emitting efficiency of the light-emitting elements 4 transferred to the driving backplane 700.

In some embodiments, each pixel group 1 of the microfluidic transfer substrate 100 includes four first pixel units 11, and the four first pixel units 11 of the same pixel group 1 are arranged to form the two-dimensional array of two rows and two columns. The multiple pixel groups 1 are arranged in the two-dimensional array. The two adjacent pixel groups 1 in the same row share two second microfluidic pixels 3, and the two adjacent pixel groups 1 in the same column share two second microfluidic pixels 3. That is, each repeating unit includes four pixel groups 1, and two adjacent pixel groups 1 along an extension direction of a side of the repeating unit share two second microfluidic pixels 3. The two pixels group 1 located on a diagonal of the repeating unit share one second microfluidic pixel 3.

In some embodiments, as illustrated in FIG. 7, the four adjacent pixel groups 1 include a total of nine first pixel units 11. The nine first pixel units 11 are distributed in three rows and three columns, thereby forming a two-dimensional array of three rows and three columns. That is, the nine first pixel units 11 of three rows and three columns form four adjacent pixel groups 1, and each pixel group is composed of two rows and two columns. Two adjacent pixel groups 1 in the same row share two second microfluidic pixels 3. That is, two adjacent pixel groups 1 in the same row share two second microfluidic pixels 3 in the middle column. Two adjacent pixel groups 1 in the same column share two second microfluidic pixels 3. That is, two adjacent pixel groups 1 in the same column share two second microfluidic pixels 3 in the middle row.

In some embodiments, as illustrated in FIG. 7, from left to right, two adjacent pixel groups 1 in a first row are the first pixel group 1 and the second pixel group 1, respectively. From left to right, two adjacent pixel groups 1 in a second row are a third pixel group 1 and a fourth pixel group 1, respectively. In the four first pixel units 11 of the first pixel group 1, the first microfluidic pixel 2 is located in the first row and first column of the two-dimensional array with two rows and two columns that is formed by the four first pixel units 11 of the first pixel group 1. In the four first pixel units 11 of the second pixel group 1, the first microfluidic pixel 2 is located in the first row and second column of the two-dimensional array with two rows and two columns that is formed by the four first pixel units 11 of the second pixel group 1. The second microfluidic pixel 3 in the first row and second column and the second microfluidic pixel 3 in the second row and second column of the first pixel group 1 are shared with the second microfluidic pixels 3 in the first row and first column and the second microfluidic pixel 3 in the second row and first column of the second pixel group 1.

In the four first pixel units 11 of the third pixel group 1, the first microfluidic pixel 2 is located in the second row and first column of the two-dimensional array with two rows and two columns that is formed by the four first pixel units 11 of the third pixel group 1. In the four first pixel units 11 of the fourth pixel group 1, the first microfluidic pixel 2 is located in the second row and second column of the two-dimensional array with two rows and two columns that is formed by the four first pixel units 11 of the fourth pixel group 1. The second microfluidic pixel 3 in the first row and second column and the second microfluidic pixel 3 in the second row and second column of the third pixel group 1 are shared with the second microfluidic pixels 3 in the first row and first column and the second microfluidic pixel 3 in the second row and first column of the second pixel group 1.

The second microfluidic pixel 3 in the second row and first column and the second microfluidic pixel 3 in the second row and second column of the first pixel group 1 are shared with the second microfluidic pixel 3 in the first row and first column and the second microfluidic pixel 3 in the first row and second column of the third pixel group 1. The second microfluidic pixel 3 in the second row and first column and the second microfluidic pixel 3 in the second row and second column of the second pixel group 1 are shared with the second microfluidic pixel 3 in the first row and first column and the second microfluidic pixel 3 in the first row and second column of the fourth pixel group 1.

In some embodiments, two adjacent pixel groups 1 in the same row share two second microfluidic pixels 3, two adjacent pixel groups 1 in the same column share two second microfluidic pixels 3, and every two adjacent pixel groups 1 of the four pixel groups 1 share at least one second microfluidic pixel 3. Therefore, the pixel density may be further increased, so as to meet more usage needs.

In some embodiments, each pixel group 1 may also include other numbers of first pixel units 11. The multiple first pixel units 11 may not be distributed in an array, the multiple pixel groups 1 may not be distributed in an array, and two adjacent pixel groups 1 may also share other numbers of second microfluidic pixels 3, which may be designed as needed.

As illustrated in FIGS. 1 and 6, in some embodiments, the microfluidic transfer substrate 100 has a transfer area Z and a liquid droplet generation area Y surrounding the transfer area Z. The multiple pixel groups 1 are disposed in the transfer area Z, and the liquid droplet generation area Y is configured to generate and transport the liquid droplets 5 containing the light-emitting elements 4 to the transfer area Z. That is, the liquid droplet 5 containing the light-emitting element 4 is first generated in the liquid droplet generation area Y, and then transported from the liquid droplet generation area Y to the pixel group 1 in the transfer area Z. The liquid droplet 5 moves in the pixel group 1, so that the light-emitting element 4 is assembled into the assembly groove 21 of the first microfluidic pixel 2. As illustrated in FIGS. 1 and 6, in some embodiments, the multiple two-dimensional array distributed pixel groups 1 in the transfer area Z form a rectangular transfer area Z, and the liquid droplet generation area Y is arranged around the periphery of the transfer area Z. That is, the liquid droplet generation area Y is arranged in a rectangular ring shape.

In some embodiments, the transfer area Z may not be rectangular, and the liquid droplet generation area Y may be disposed at any position in the transfer area Z. That is, the liquid droplet generation area Y may not be disposed around the transfer area Z. In some embodiments, the liquid droplet generation area Y may be disposed only on one side or both sides of the transfer area Z, as long as it may ensure that the liquid droplet generation area Y may generate the liquid droplets 5 containing the light-emitting elements 4 and may be communicated with the transfer area Z, so as to transport the liquid droplets 5 containing the light-emitting elements 4 to the transfer area Z, which may not be limited in the present disclosure.

In some embodiments, the microfluidic transfer substrate 100 may not have the liquid droplet generation area Y, that is, the microfluidic transfer substrate 100 may only have the transfer area Z. The liquid droplet 5 containing the light-emitting element 4 may be directly generated and transported to the area where different pixel groups 1 in the transfer area Z are located by disposing other structural components.

In some embodiments, multiple liquid droplets 5 containing the light-emitting elements 4 may be uniformly generated by mixing a solution (not illustrated in figures) and the light-emitting elements 4 in the liquid droplet generation area Y, and then the liquid droplets 5 containing the light-emitting elements 4 may be transported from the liquid droplet generation area Y to the pixel groups 1 in the transfer area Z.

In some embodiments, a specific structural component (not illustrated in figures) may be disposed to directly generate the liquid droplet 5 containing the light-emitting element 4 and directly transport the liquid droplet 5 containing the light-emitting element 4 to each pixel group 1. That is, the liquid droplet generation area Y may be omitted, and the liquid droplet 5 containing the light-emitting element 4 may be directly generated and transported by the structural component. In some embodiments, the structural component may be a print head, and the print head may be located above the microfluidic transfer substrate 100, and may move between areas corresponding to different pixel groups 1. The liquid droplet 5 containing the light-emitting element 4 may be directly dropped onto areas of the microfluidic transfer substrate 100 where different pixel groups 11 are located, so that each pixel group 1 contains one liquid droplet 5 containing the light-emitting element 4, which facilitates the assembly of the light-emitting elements 4, thereby facilitating the mass transfer of the light-emitting elements 4.

As illustrated in FIGS. 1 and 6, in some embodiments, the liquid droplet generation area Y includes multiple second pixel units 6, and a structure of the second pixel unit 6 is the same as that of the second microfluidic pixel 3. That is, a surface of the second pixel unit 6 does not define the assembly groove 21. All the first pixel units 11 in the transfer area Z and all the second pixel units 6 in the liquid droplet generation area Y are arranged in the two-dimensional array. That is, the multiple second pixel units 6 in the liquid droplet generation area Y and the multiple first pixel units 11 in the transfer area Z together form the two-dimensional array. The multiple second pixel units 6 in the liquid droplet generation area Y are located in the row or the column where the first pixel units 11 in the transfer area Z are located. The multiple second pixel units 6 are disposed in the liquid droplet generation area Y, and the second pixel units 6 and all the first pixel units 11 in the transfer area Z are distributed together in the two-dimensional array. Therefore, during transporting the liquid droplet 5 containing the light-emitting element 4 generated in the liquid droplet generation area Y to the pixel group 1 in the transfer area Z, the second pixel unit 6 may be configured to serve as a transport channel for the liquid droplet 5. It is more convenient for driving the liquid droplet 5 containing the light-emitting element 4 to be transported to the position of the pixel group 1, shortening a transport path of the liquid droplet 5, and improving the transport efficiency of the liquid droplets 5, thereby improving the assembly efficiency of the light-emitting elements 4.

In some embodiments, the liquid droplet generation area Y may not have the second pixel unit 6, the liquid droplet generation area Y may be set only around the transfer area Z, and the liquid droplet 5 containing the light-emitting element 4 is only generated in the liquid droplet generation area Y. The liquid droplets 5 containing the light-emitting elements 4 generated in the liquid droplet generation area Y may move in any direction or trajectory in the liquid droplet generation area Y, as long as the liquid droplets 5 containing the light-emitting elements 4 may be transported from the liquid droplet generation area Y to the transfer area Z.

In some embodiments, as illustrated in FIG. 1, the multiple pixel groups 1 in the transfer area Z of the microfluidic transfer substrate 100 are distributed in the two-dimensional array and form the rectangular transfer area Z. The liquid droplet generation area Y is set around the rectangular transfer area Z. The liquid droplet 5 containing the light-emitting element 4 generated in the liquid droplet generation area Y may enter the transfer area Z from a direction perpendicular to any one or more of four sides of the transfer area Z. Therefore, the liquid droplet 5 containing the light-emitting element 4 in the liquid droplet generation area Y is transported to the area where the pixel group 1 in the transfer area Z is located.

In some embodiments, in a case where the multiple pixel groups 1 in the transfer area Z are randomly distributed, the liquid droplet 5 containing the light-emitting element 4 in the liquid droplet generation area Y may also enter the area where the pixel group 1 is located from any other directions, which may be designed as needed.

In some embodiments, the microfluidic transfer substrate 100 only transmits light at the position of the assembly groove 21. In some embodiments, as illustrated in FIG. 3, each of the first pixel unit 11 and the second pixel unit 6 includes a substrate 12, a thin film transistor (TFT) 13, a first insulating layer 14, a planarization layer 15, a microfluidic electrode layer 16, a second insulating layer 17, and a hydrophobic layer 18 arranged in sequence. The planarization layer 15 is an opaque layer, and the assembly groove 21 penetrates through the opaque layer.

In some embodiments, as illustrated in FIG. 3, the thin film transistor 13 is disposed on the substrate 12. The thin film transistor 13 includes a gate metal layer 131, a gate insulation layer 132, an active layer 133, and a source drain metal layer 134 stacked in sequence. The gate insulation layer 132 is disposed on a side of the gate metal layer 131 away from the substrate 12 and covers the gate metal layer 131 and the substrate 12. The active layer 133 is disposed at a position corresponding to the gate metal layer 131 and partially covers the gate insulation layer 132. The source drain metal layer 134 is disposed on a side of the active layer 133 away from the substrate 12, and covers a part of the active layer 133 and a part of the gate insulation layer 132. The source drain metal layer 134 includes a source electrode (not labeled in the figure) and a drain electrode (not labeled in the figure) arranged at intervals. A part of the active layer 133 is exposed at a position where the drain electrode and source electrode are spaced apart from each other. The first insulation layer 14 is located on a side of the source drain metal layer 134 away from the substrate 12, and covers the source drain metal layer 134, the active layer 133, and the gate insulation layer 132. The planarization layer 15, the microfluidic electrode layer 16, the second insulation layer 17, and the hydrophobic layer 18 are disposed on a surface of the first insulation layer 14 away from the substrate 12. The planarization layer 15 defines a via hole 151 spaced apart from the assembly groove 21. The via hole 151 sequentially penetrates through the planarization layer 15 and the first insulation layer 14, and expose a part of the source drain metal layer 134. The microfluidic electrode layer 16 covers the sidewall of the via hole 151 and is in contact with the source drain metal layer 134.

In some embodiments, as illustrated in FIG. 3, the planarization layer 15 is a black material layer, and the black material layer defines a through hole to expose a part of the first insulation layer 14, thereby forming the assembly groove 21.

In some embodiments, the microfluidic electrode layer 16 is a transparent conductive layer. The microfluidic electrode layer 16 may be a single continuous layer, or the microfluidic electrode layer 16 defines an opening 161 corresponding to the assembly groove 21. In some embodiments, the microfluidic electrode layer 16 may be a transparent conductive layer of indium tin oxide (ITO). As illustrated in FIG. 3, in some embodiments, the microfluidic electrode layer 16 defines the opening 161 at a position corresponding to the assembly groove 21. That is, the microfluidic electrode layer 16 is not disposed in the assembly groove 21, and the opening 161 of the microfluidic electrode layer 16 directly exposes the assembly groove 21 and a part of the first insulation layer 14. In some embodiments, since the microfluidic electrode layer 16 is the transparent conductive layer, light may penetrate through the microfluidic electrode layer 16. Therefore, the microfluidic electrode layer 16 may not define the opening 161 at the position corresponding to the assembly groove 21, and the planarization layer 15 and the side surface and the bottom surface of the assembly groove 21 may be directly covered by the microfluidic electrode layer 16.

In some embodiments, the microfluidic electrode layer 16 may be the opaque layer, and the microfluidic electrode layer 16 defines the opening 161 at the position corresponding to the assembly groove 21. Since the microfluidic electrode layer 16 is the opaque layer, the opening 161 is defined at the position of the microfluidic electrode layer 16 corresponding to the assembly groove 21, so that the assembly groove 21 is exposed and the position of the assembly groove 21 may still transmit light.

That is, in some embodiments, the microfluidic electrode layer 16 is the transparent conductive layer, and the microfluidic electrode layer 16, the second insulation layer 17, and the hydrophobic layer 18 may all cover the bottom surface and the side surface of the assembly groove 21. In some embodiments, as illustrated in FIG. 3, the microfluidic electrode layer 16 may only be disposed on the surface of the black planarization layer 15 away from the substrate 12 and defines the opening 161 corresponding to the assembly groove 21, and the second insulation layer 17 and the hydrophobic layer 18 may all cover the bottom surface and the side surface of the assembly groove 21.

In the present embodiment, the microfluidic transfer substrate 100 only transmits light at the position of the assembly groove 21. During driving the liquid droplet 5 containing the light-emitting element 4 to assemble the light-emitting element 4 into the assembly groove 21 of the first microfluidic pixel 2, the assembly groove 21 is filled with the light-emitting element 4. In a case where the light irradiates the microfluidic transfer substrate 100, the light passing through the assembly groove 21 may be greatly reduced, and even the position of the assembly groove 21 may no longer transmit light. Therefore, the microfluidic transfer substrate 100 may be irradiated by a light source or the like, so as to detect or determine whether the light-emitting element 4 is assembled in the assembly groove 21. And accordingly, the position of the first microfluidic pixel 2 that is not assembled with the light-emitting element 4 may be screened out for subsequent operations, such as secondary assembly.

By using the microfluidic transfer substrate 100 provided in the present disclosure, two adjacent pixel groups 1 share at least one second microfluidic pixel 3. It may effectively increase the pixel density of the first microfluidic pixels 2 of the microfluidic transfer substrate 100 and increase the assembly density of the light-emitting element 4, thereby improving the light-emitting efficiency of the light-emitting elements 4 transferred to the driving backplane 700.

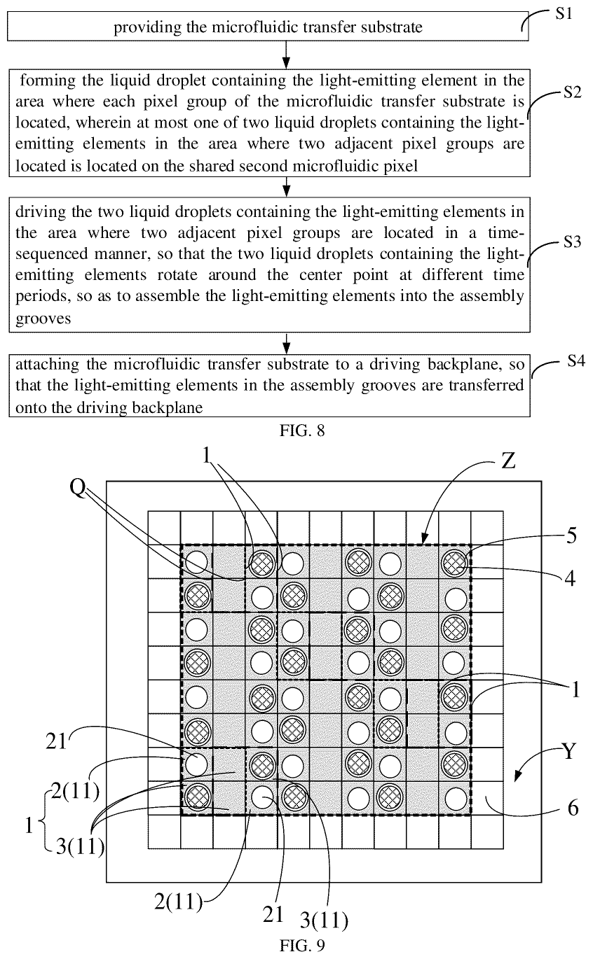

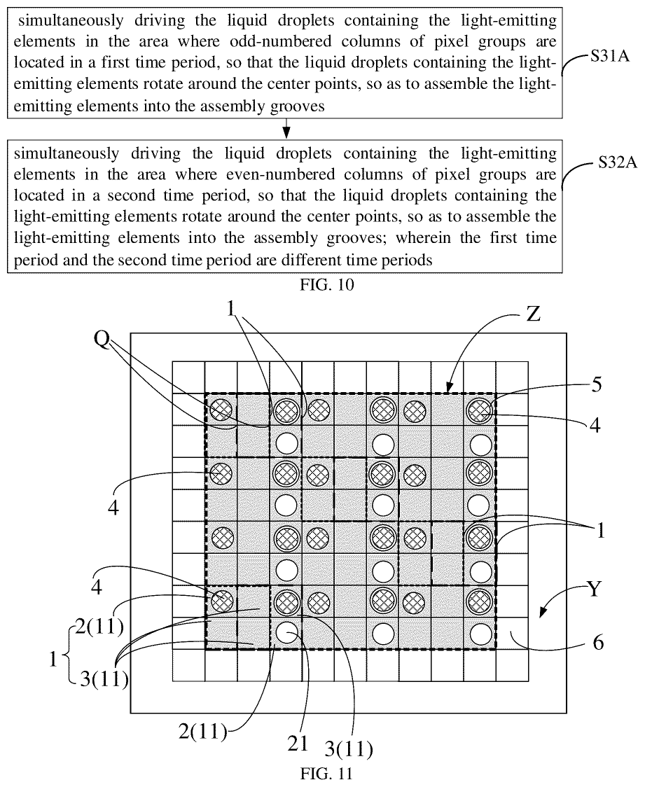

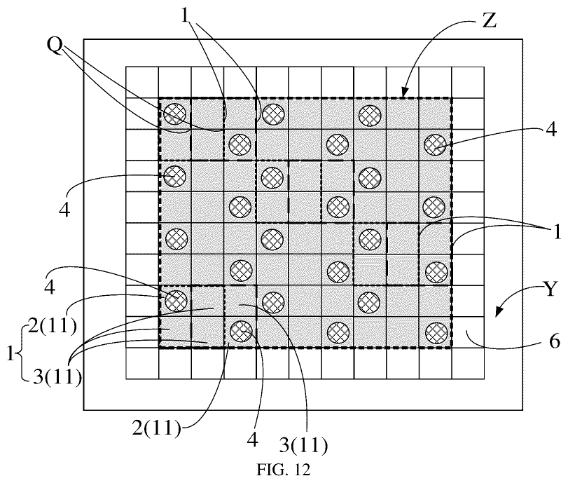

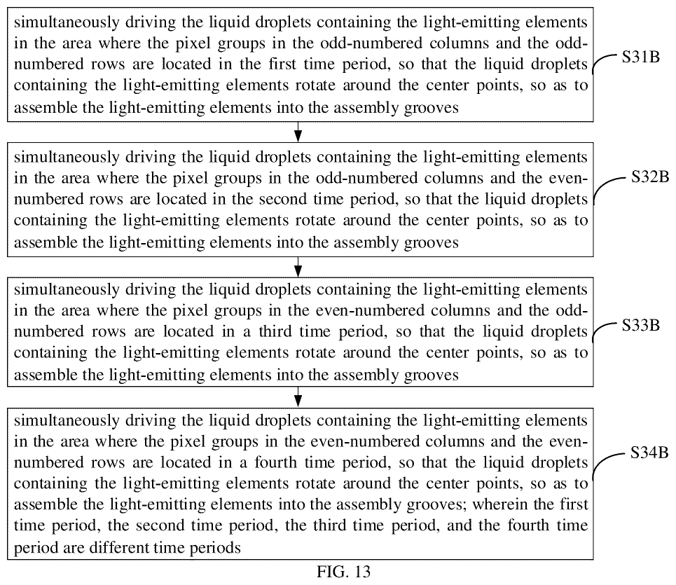

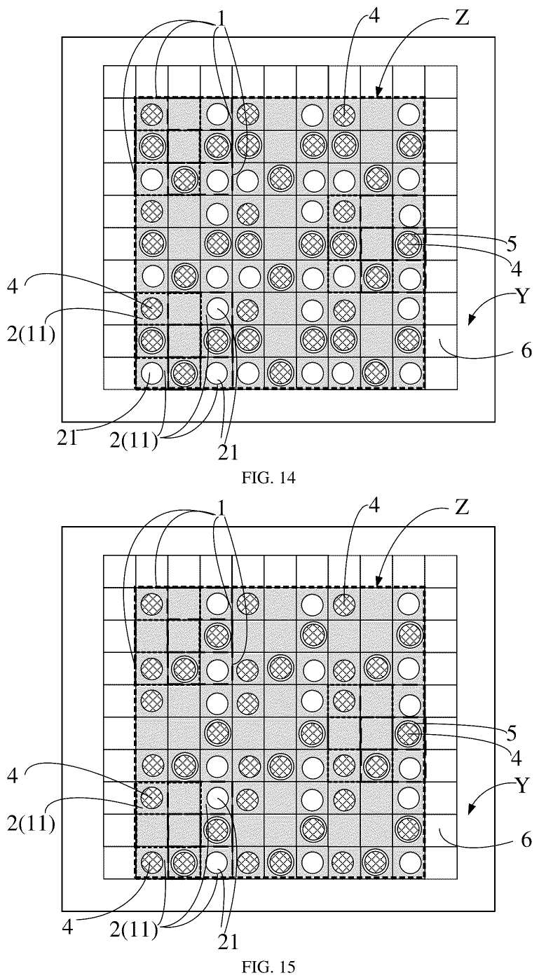

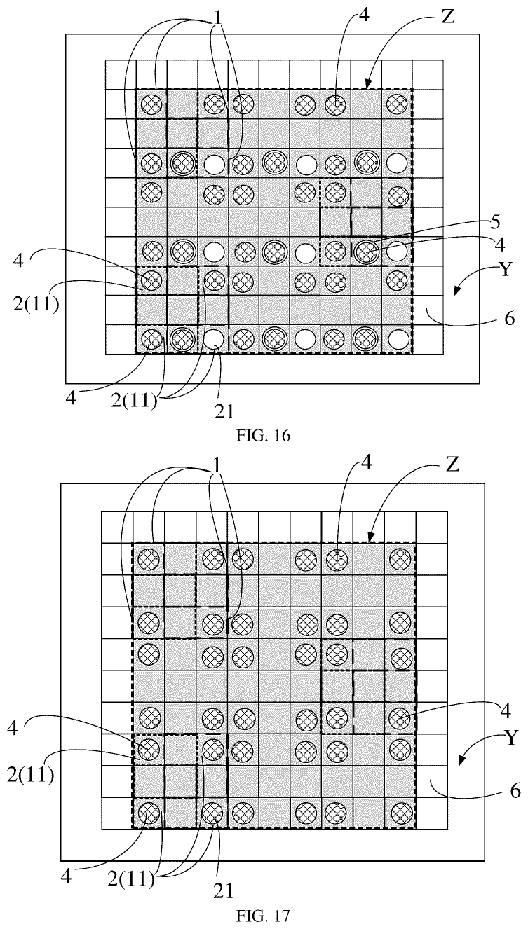

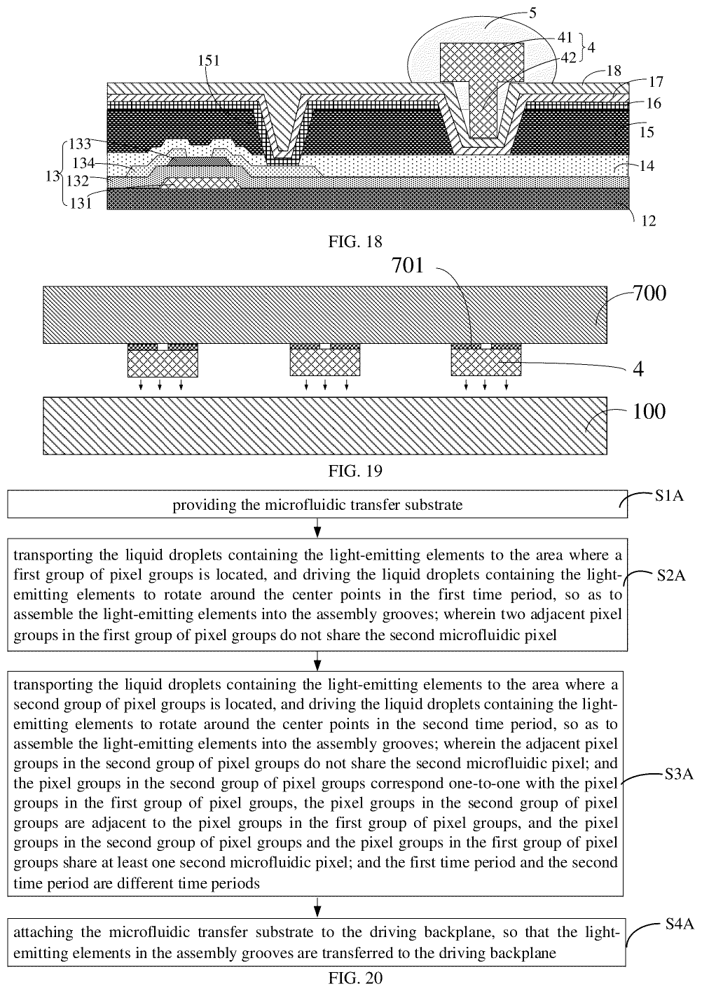

As illustrated in FIGS. 8 to 19, FIG. 8 is a flowchart of a first embodiment of a method for transferring light-emitting elements in the present disclosure. FIG. 9 is a structural schematic view corresponding to an embodiment of an operation at block S2 of FIG. 8. FIG. 10 is a flowchart of an embodiment of an operation at block S3 of FIG. 8. FIG. 11 is a structural schematic view corresponding to an operation at block S31A of FIG. 10. FIG. 12 is a structural schematic view corresponding to an operation at block S32A of FIG. 10. FIG. 13 is a flowchart of another embodiment of the operation at block S3 of FIG. 8. FIG. 14 is a structural schematic view corresponding to an operation at block S31B of FIG. 13. FIG. 15 is a structural schematic view corresponding to an operation at block S32B of FIG. 13. FIG. 16 is a structural schematic view corresponding to an operation at block S33B of FIG. 13. FIG. 17 is a structural schematic view corresponding to an operation at block S34B of FIG. 13. FIG. 18 is a cross-sectional structural schematic view of a structure of FIG. 12. FIG. 19 is a structural schematic view corresponding to an operation at block S4 of FIG. 8.

As illustrated in FIG. 8, the present disclosure further provides a method for transferring the light-emitting elements 4, which is configured to achieve mass transfer of the light-emitting elements 4. The method for transferring the light-emitting elements 4 includes the following operations.

At block S1, the method for transferring the light-emitting elements 4 may include providing the microfluidic transfer substrate 100.

In some embodiments, the microfluidic transfer substrate 100 is provided and may be the microfluidic transfer substrate 100 as described in any one of the embodiments.

At block S2, the method for transferring the light-emitting elements 4 may include forming the liquid droplet 5 containing the light-emitting element 4 in the area where each pixel group 1 of the microfluidic transfer substrate 100 is located, wherein at most one of two liquid droplets 5 containing the light-emitting elements 4 in the area where two adjacent pixel groups 1 are located is located on the shared second microfluidic pixel 3.

In some embodiments, the liquid droplet 5 containing the light-emitting element 4 is formed in the area where each pixel group 1 of the microfluidic transfer substrate 100 is located. That is, each pixel group 1 contains the liquid droplet 5 containing the light-emitting element 4. The liquid droplet 5 containing the light-emitting element 4 is formed in the area where each pixel group 1 of the microfluidic transfer substrate 100 is located, which is conducive to improving the assembly yield of the light-emitting elements 4, thereby improving the transfer efficiency of the mass transfer of the light-emitting elements 4.

In some embodiments, the area where some pixel groups 1 of the microfluidic transfer substrate 100 are located may not have the liquid droplets 5 containing the light-emitting elements 4. That is, only some pixel groups 1 of the microfluidic transfer substrate 100 have the liquid droplets 5 containing the light-emitting elements 4.

In some embodiments, as illustrated in FIG. 9, in some embodiments, the microfluidic transfer substrate 100 has the transfer area Z and the liquid droplet generation area Y adjacent to the transfer area Z. The multiple pixel groups 1 of the microfluidic transfer substrate 100 are located in the transfer area Z, and the liquid droplet generation area Y is configured to generate the liquid droplets 5 containing the light-emitting elements 4. Since the liquid droplet generation area Y is adjacent to the transfer area Z, the liquid droplets 5 containing the light-emitting elements 4 generated in the liquid droplet generation area Y may be transported to the transfer area Z. By controlling the liquid droplet generation area Y to generate and transport the liquid droplets 5 containing the light-emitting elements 4 to the transfer area Z, and controlling each of the liquid droplets 5 containing the light-emitting elements 4 to move to the area where corresponding pixel group 1 in the transfer area Z is located, the liquid droplet 5 containing the light-emitting element 4 may be formed in the area where each pixel group 1 of the microfluidic transfer substrate 100 is located.

The two adjacent pixel groups 1 of the microfluidic transfer substrate 100 in the present disclosure share at least one second microfluidic pixel 3. Therefore, at most one of the two liquid droplets 5 containing the light-emitting elements 4 in the area where two adjacent pixel groups 1 are located is located on the shared second microfluidic pixel 3. It prevents the multiple liquid droplets 5 containing the light-emitting elements 4 from being located on the shared second microfluidic pixel 3. In a case where the liquid droplets 5 containing the light-emitting elements 4 in the pixel groups 1 are subsequently driven to swing back and forth between the first microfluidic pixel 2 and the multiple second microfluidic pixels 3 of pixel group 1 or rotate around the center point Q, the other liquid droplets 5 containing the light-emitting elements 4 on the shared second microfluidic pixel 3 would block the movement channel or interfere with the normal movement of the liquid droplets 5 containing the light-emitting elements 4. This would cause the liquid droplets 5 containing the light-emitting elements 4 in the pixel groups 1 to be unable to move normally, and the light-emitting elements 4 would not be able to be assembled into the assembly grooves 21. By avoiding this issue, the assembly efficiency and the assembly accuracy of the light-emitting elements 4 are ensured, which is conducive to improving the assembly yield.

In some embodiments, the liquid droplet 5 containing the light-emitting element 4 is controlled to move, along the row or column where the second microfluidic pixel 3 shared by two adjacent pixel groups 1 (which do not have the first microfluidic pixel 2) is located, to the area where corresponding pixel group 1 is located. The liquid droplet 5 containing the light-emitting element 4 is controlled to stay on the non-shared second microfluidic pixel 3 in the pixel group 1. It is more conducive to improving the transport efficiency of the liquid droplets 5 containing the light-emitting elements 4, and improving the assembly efficiency and the assembly accuracy, thereby improving the assembly yield.

In some embodiments, the liquid droplet 5 containing the light-emitting element 4 may also be controlled to move along any other direction or trajectory to the area where the corresponding pixel group 1 is located, so that each area where the pixel group 1 is located has the liquid droplet 5 containing the light-emitting element 4. Alternatively, the microfluidic transfer substrate 100 may not have the liquid droplet generation area Y, or specific structural components may be disposed to directly generate the liquid droplet 5 containing the light-emitting element 4 and directly transport the liquid droplet 5 containing the light-emitting element 4 to the area where each pixel group 1 is located. In some embodiments, the structural component may be located above the microfluidic transfer substrate 100 and may move between the areas corresponding to different pixel groups 1, so that the liquid droplets 5 containing the light-emitting elements 4 are directly dropped into different areas of the microfluidic transfer substrate 100, and each pixel group 1 has the liquid droplet 5 containing the light-emitting element 4.

At block S3, the method for transferring the light-emitting elements 4 may include driving the two liquid droplets 5 containing the light-emitting elements 4 in the area where two adjacent pixel groups 1 are located in a time-sequenced manner, so that the two liquid droplets 5 containing the light-emitting elements 4 rotate around the center point Q at different time periods, so as to assemble the light-emitting elements 4 into the assembly grooves 21.

In some embodiments, the two liquid droplets 5 containing the light-emitting elements 4 in the area where the two adjacent pixel groups 1 are located are driven in a time-sequenced manner, so that each of the two liquid droplets 5 containing the light-emitting elements 4 rotates around the center point Q of the corresponding pixel group 1 at different time periods, so as to assemble each light-emitting element 4 into the corresponding assembly groove 21. In some embodiments, the above-mentioned driving in a time-sequenced manner refers to: first, the first pixel units 11 of one pixel group 1 of the two adjacent pixel groups 1 drive the liquid droplet 5 containing the light-emitting element 4 to rotate around the center point Q of this pixel group 1, so as to assemble the light-emitting element 4 into the assembly groove 21 of the first microfluidic pixel 2 of this pixel group 1. Then, the first pixel units 11 of the other pixel group 1 of the two adjacent pixel groups 1 drive the liquid droplet 5 containing the light-emitting element 4 to rotate around the center point Q of this pixel group 1, so as to assemble the light-emitting element 4 into the corresponding assembly groove 21.

In some embodiments, the microfluidic transfer substrate 100 in the operation at block S1 is the microfluidic transfer substrate 100 as illustrated in FIG. 1 or 4. That is, the multiple pixel groups 1 are arranged in the two-dimensional array, each pixel group 1 includes four first pixel units 11, and the four first pixel units 11 of the same pixel group 1 are arranged to form the two-dimensional array of two rows and two columns. The two adjacent pixel groups 1 in the same row share two second microfluidic pixels 3, and the two adjacent pixel groups 1 in the same column do not share the second microfluidic pixels 3.

As illustrated in FIG. 10, in some embodiments, the driving the two liquid droplets 5 containing the light-emitting elements 4 in the area where two adjacent pixel groups 1 are located in a time-sequenced manner, as described in the operation at block S3, includes the following operations.

At block S31A, the operation at block S3 may include simultaneously driving the liquid droplets 5 containing the light-emitting elements 4 in the area where odd-numbered columns of pixel groups 1 are located in a first time period, so that the liquid droplets 5 containing the light-emitting elements 4 rotate around the center points Q, so as to assemble the light-emitting elements 4 into the assembly grooves 21.

In some embodiments, in the first time period, the liquid droplets 5 containing the light-emitting elements 4 in the area where odd-numbered columns of pixel groups 1 are located is driven, so that the liquid droplets 5 containing the light-emitting elements 4 swing back and forth between the first microfluidic pixel 2 and the three second microfluidic pixels 3 in the odd-numbered columns of pixel groups 1 or rotate around the center point Q, so as to assemble the light-emitting elements 4 into the assembly grooves 21 of the first microfluidic pixels 2 in the odd-numbered columns of pixel groups 1, thereby completing the assembly of the light-emitting elements 4 in the odd-numbered columns of pixel groups 1. That is, all pixel groups 1 located in the odd-numbered columns of the two-dimensional array on the microfluidic transfer substrate 100 are uniformly assembled with the light-emitting elements 4 in the first time period. In the first time period, the liquid droplets 5 containing the light-emitting elements 4 in all pixel groups 1 located in even-numbered columns are not driven. That is, the liquid droplets 5 containing the light-emitting elements 4 in all pixel groups 1 in the even-numbered columns are still in their original positions. This may prevent interference or collision in a case where the liquid droplets 5 containing the light-emitting elements 4 in the pixel groups 1 in the odd-numbered columns and the even-numbered columns move simultaneously. This interference or collision may cause the light-emitting elements 4 to be unable to be accurately and effectively assembled into the assembly grooves 21 of the first microfluidic pixels 2. By avoiding this issue, the assembly efficiency, the assembly accuracy, and the assembly yield may be improved.

In some embodiments, after the operation at block S31A, the light-emitting elements 4 of the odd-numbered columns of pixel groups 1 are all assembled into the assembly grooves 21, the structure illustrated in FIG. 11 may be obtained.

At block S32A, the operation at block S3 may include simultaneously driving the liquid droplets 5 containing the light-emitting elements 4 in the area where even-numbered columns of pixel groups 1 are located in a second time period, so that the liquid droplets 5 containing the light-emitting elements 4 rotate around the center points Q, so as to assemble the light-emitting elements 4 into the assembly grooves 21; wherein the first time period and the second time period are different time periods.

In some embodiments, in the second time period, the liquid droplets 5 containing the light-emitting elements 4 in the area where the even-numbered columns of pixel groups 1 are located are simultaneously driven, so that the liquid droplets 5 containing the light-emitting elements 4 may swing back and forth between the first microfluidic pixel 2 and the three second microfluidic pixels 3 in the even-numbered columns of pixel groups 1 or rotate around the center point Q, so as to assemble the light-emitting elements 4 into the assembly grooves 21 of the first microfluidic pixels 2 in the even-numbered columns of pixel groups 1, thereby completing the assembly of the light-emitting elements 4 in the even-numbered columns of pixel groups 1. That is, all pixel groups 1 located in the even-numbered columns of two-dimensional array on the microfluidic transfer substrate 100 are uniformly assembled with the light-emitting elements 4 in the second time period. Due to the fact that the first time period and the second time period are different time periods, there is a chronological order and there is no intersection between the first time period and the second time period. Therefore, in the second time period, the liquid droplets 5 containing the light-emitting elements 4 in all pixel groups 1 located in odd-numbered columns are not driven. This may prevent interference or collision in a case where the liquid droplets 5 containing the light-emitting elements 4 in the pixel groups 1 in the odd-numbered columns and the even-numbered columns move simultaneously. This interference or collision may cause the light-emitting elements 4 to be unable to be accurately and effectively assembled into the assembly grooves 21 of the first microfluidic pixels 2. By avoiding this issue, the assembly efficiency, the assembly accuracy, and the assembly yield may be improved.

In some embodiments, the first time period may be before or after the second time period, and the order of the first time period and the second time period may be randomly set, as long as there is no intersection between the first time period and the second time period. In some embodiments, the first time period may be before the second time period. After the operation at block S31A of assembling the light-emitting elements 4 in the odd-numbered columns of pixel groups 1 into the assembly grooves 21, and then after the operation at block S32A of assembling the light-emitting elements 4 in the even-numbered columns of pixel groups 1 into the assembly grooves 21, the structure illustrated in FIG. 12 may be obtained. Each of all light-emitting elements 4 in the odd-numbered columns of pixel groups 1 and the even-numbered columns of pixel groups 1 is assembled into the corresponding assembly groove 21, completing the assembly of all light-emitting elements 4 on the microfluidic transfer substrate 100.

In some embodiments, the microfluidic transfer substrate 100 in the operation at block S1 is the microfluidic transfer substrate 100 illustrated in FIG. 6. That is, the multiple pixel groups 1 are arranged in the two-dimensional array, each pixel group 1 includes four first pixel units 11, and the four first pixel units 11 of the same pixel group 1 are arranged to form the two-dimensional array of two rows and two columns. The two adjacent pixel groups 1 in the same row share two second microfluidic pixels 3, and the two adjacent pixel groups 1 in the same column share two second microfluidic pixels 3.

As illustrated in FIG. 13, in some embodiments, the driving the two liquid droplets 5 containing the light-emitting elements 4 in the area where two adjacent pixel groups 1 are located in a time-sequenced manner, as described in the operation at block S3, includes the following operations.

At block S31B, the operation at block S3 may include simultaneously driving the liquid droplets 5 containing the light-emitting elements 4 in the area where the pixel groups 1 in the odd-numbered columns and the odd-numbered rows are located in the first time period, so that the liquid droplets 5 containing the light-emitting elements 4 rotate around the center points Q, so as to assemble the light-emitting elements 4 into the assembly grooves 21.

In some embodiments, two adjacent pixel groups 1 in the same row share two second microfluidic pixels 3, two adjacent pixel groups 1 in the same column share two second microfluidic pixels 3, and the nine first pixel units 11 in three rows and three columns form four adjacent pixel groups 1 in two rows and two columns. Therefore, the liquid droplets 5 containing the light-emitting elements 4 in the area where the pixel groups 1 in the odd-numbered columns and the odd-numbered rows are located are simultaneously driven in the first time period, which may cause each of the liquid droplets 5 containing the light-emitting elements 4 in the pixel groups 1 to rotate around the corresponding center point Q, or swing back and forth between the first microfluidic pixel 2 and the three second microfluidic pixels in the corresponding pixel group 1, so as to assemble each light-emitting element 4 into the corresponding assembly groove 21. In the first time period, the liquid droplets 5 containing the light-emitting elements 4 in the area where other pixel groups 1 are located are not driven, so that the movement of the liquid droplets 5 containing the light-emitting elements 4 in the pixel groups 1 in the odd-numbered columns and the odd-numbered rows is not affected.

That is, the liquid droplets 5 containing the light-emitting elements 4 in the area where the pixel groups 1 in the odd-numbered columns and the odd-numbered rows are located, which are distributed in an array on the microfluidic transfer substrate 100, are uniformly driven in the first time period, thereby completing the assembly of the light-emitting elements 4.

In some embodiments, after the operation at block S31B, the light-emitting elements 4 of the pixel groups 1 located in the odd-numbered columns and the odd-numbered rows are all assembled into the assembly grooves 21, so that the structure illustrated in FIG. 14 may be obtained.

At block S32B, the operation at block S3 may include simultaneously driving the liquid droplets 5 containing the light-emitting elements 4 in the area where the pixel groups 1 in the odd-numbered columns and the even-numbered rows are located in the second time period, so that the liquid droplets 5 containing the light-emitting elements 4 rotate around the center points Q, so as to assemble the light-emitting elements 4 into the assembly grooves 21.

In some embodiments, in the second time period, the liquid droplets 5 containing the light-emitting elements 4 in the area where the pixel group 1 in the odd-numbered columns and the even-numbered rows are located are simultaneously driven, which may cause each of the liquid droplets 5 containing the light-emitting elements 4 in the pixel groups 1 to rotate around the corresponding center point Q, or swing back and forth between the first microfluidic pixel 2 and the three second microfluidic pixels 3 in the corresponding pixel group 1, so as to assemble each light-emitting element 4 into the corresponding assembly groove 21.

The second time period and the first time period are different time periods, and there is a chronological order and there is no intersection between the first time period and the second time period. In the second time period, only the liquid droplets 5 containing the light-emitting elements 4 in the area where the pixel groups 1 in the odd-numbered columns and the even-numbered rows are located are driven, while the liquid droplets 5 containing the light-emitting elements 4 in the pixel groups 1 at other positions are not driven. Therefore, interference of the movement of the liquid droplets 5 containing the light-emitting elements 4 in the pixel groups 1 in the odd-numbered columns and the even-numbered rows may be avoided.

In some embodiments, the first time period may be before or after the second time period, and the order of the first time period and the second time period may be randomly set, as long as there is no intersection between the first time period and the second time period. In some embodiments, the first time period may be before the second time period. After the operation at block S31B of assembling the light-emitting elements 4 of the pixel groups 1 in the odd-numbered columns and the odd-numbered rows into the assembly grooves 21, and then after the operation at block S32B of assembling the light-emitting elements 4 of the pixel groups 1 in the odd-numbered columns and the even-numbered rows into the assembly grooves 21, the structure illustrated in FIG. 15 may be obtained. Each light-emitting element 4 of all pixel groups 1 in the odd-numbered columns and the odd-numbered rows is assembled into the corresponding assembly groove 21, and each light-emitting element 4 of all pixel groups 1 in the odd-numbered columns and the even-numbered rows is assembled into the corresponding assembly groove 21. That is, each of all the light-emitting elements 4 of the pixel groups 1 in the odd-numbered columns is assembled into the corresponding assembly groove 21, thereby completing the assembly of the light-emitting elements 4 of all pixel groups 1 in the odd-numbered columns.

At block S33B, the operation at block S3 may include simultaneously driving the liquid droplets 5 containing the light-emitting elements 4 in the area where the pixel groups 1 in the even-numbered columns and the odd-numbered rows are located in a third time period, so that the liquid droplets 5 containing the light-emitting elements 4 rotate around the center points Q, so as to assemble the light-emitting elements 4 into the assembly grooves 21.

In some embodiments, in the third time period, the liquid droplets 5 containing the light-emitting elements 4 in the area where the pixel groups 1 in the even-numbered columns and the odd-numbered rows are located are simultaneously driven, which may cause each of the liquid droplets 5 containing the light-emitting elements 4 in the pixel groups 1 to rotate around the corresponding center point Q, or swing back and forth between the first microfluidic pixel 2 and the three second microfluidic pixels 3 in the corresponding pixel group 1, so as to assemble each light-emitting element 4 into the corresponding assembly groove 21.

The third time period, the second time period, and the first time period are all different time periods. The three time periods have a chronological order and do not intersect. In the third time period, only the liquid droplets 5 containing the light-emitting elements 4 in the area where the pixel groups 1 in the even-numbered columns and the odd-numbered rows are located are driven, while the liquid droplets 5 containing the light-emitting elements 4 in the pixel group 1 at other positions are not driven, so that the interference of the movement of the liquid droplets 5 containing the light-emitting elements 4 in the pixel groups 1 in the even-numbered columns and the odd-numbered rows may be avoided.

In some embodiments, the order of the third time period, the second time period, and the first time period may be randomly set, as long as there is no intersection among the three time periods. In some embodiments, the first time period is before the second time period, and the second time period is before the third time period. After the operation at block S31B of assembling the light-emitting elements 4 of the pixel groups 1 in the odd-numbered columns and the odd-numbered rows into the assembly grooves 21, then after the operation at block S32B of assembling the light-emitting elements 4 of the pixel groups 1 in the odd-numbered columns and the even-numbered rows into the assembly grooves 21, and then after the operation at block S33B of assembling the light-emitting elements 4 of the pixel groups 1 in the even-numbered columns and the odd-numbered rows into the assembly grooves 21, the structure illustrated in FIG. 16 may be obtained. Each light-emitting element 4 of the pixel groups 1 in the even-numbered columns and the odd-numbered rows is assembled into the corresponding assembly groove 21, and each light-emitting element 4 of the pixel groups 1 in the odd-numbered columns is assembled into the corresponding assembly groove 21, thereby completing the assembly of all light-emitting elements 4 of the pixel groups 1 in the even-numbered columns and the odd-numbered rows, and completing the assembly of all light-emitting elements 4 of the pixel groups 1 in the odd-numbered columns.

At block S34B, the operation at block S3 may include simultaneously driving the liquid droplets 5 containing the light-emitting elements 4 in the area where the pixel groups 1 in the even-numbered columns and the even-numbered rows are located in a fourth time period, so that the liquid droplets 5 containing the light-emitting elements 4 rotate around the center points Q, so as to assemble the light-emitting elements 4 into the assembly grooves 21; wherein the first time period, the second time period, the third time period, and the fourth time period are different time periods.

In some embodiments, in the fourth time period, the liquid droplets 5 containing the light-emitting elements 4 in the area where the pixel groups 1 in the even-numbered columns and the even-numbered rows are located are simultaneously driven, so that each of the liquid droplets 5 containing the light-emitting elements 4 in the pixel groups 1 rotates around the corresponding center point Q, or swings back and forth between the first microfluidic pixel 2 and the three second microfluidic pixels 3 in the corresponding pixel group 1, so as to assemble each light-emitting element 4 into the corresponding assembly groove 21.

The fourth time period, the third time period, the second time period, and the first time period are all different time periods. The four time periods have a chronological order and do not intersect. In the fourth time period, only the liquid droplets 5 containing the light-emitting elements 4 in the area where the pixel groups 1 in the even-numbered columns and the even-numbered rows are located are driven, while the liquid droplets 5 containing the light-emitting elements 4 in the pixel groups 1 at other positions are not driven, so that the interference of the movement of the liquid droplets 5 containing the light-emitting elements 4 in the pixel groups 1 in the even-numbered columns and the even-numbered rows may be avoided.

In some embodiments, the order of the fourth time period, the third time period, the second time period, and the first time period may be randomly set, as long as there is no intersection among the four time periods. In some embodiments, the first time period is before the second time period, the second time period is before the third time period, and the third time period is before the fourth time period. After the operation at block S31B of assembling the light-emitting elements 4 of the pixel groups 1 in the odd-numbered columns and the odd-numbered rows into the assembly grooves 21, then after the operation at block S32B of assembling the light-emitting elements 4 of the pixel groups 1 in the odd-numbered columns and the even-numbered rows into the assembly grooves 21, then after the operation at block S33B of assembling the light-emitting elements 4 of the pixel groups 1 in the even-numbered columns and the odd-numbered rows into the assembly grooves 21, and finally after the operation at block S34B of assembling the light-emitting elements 4 of the pixel groups 1 in the even-numbered columns and the even-numbered rows into the assembly grooves 21, the structure illustrated in FIG. 17 may obtained. Each light-emitting element 4 of the pixel groups 1 in the even-numbered columns and the odd-numbered columns of the microfluidic transfer substrate 100 is assembled into the corresponding assembly groove 21, thereby completing the assembly of the light-emitting elements 4 of all pixel groups 1 of the microfluidic transfer substrate 100.

In some embodiments, the order of the first time period, the second time period, the third time period, and the fourth time period may also be randomly set, as long as it ensures that only the liquid droplets 5 containing the light-emitting elements 4 in the area where multiple pixel groups 1 of the same specific position type are located are driven during a certain time period. Alternatively, the liquid droplets 5 containing the light-emitting elements 4 may be randomly driven. In some embodiments, the liquid droplets 5 containing the light-emitting elements 4 in the area where multiple pixel groups 1 are located may be driven in sequence according to the arrangement order of pixel groups 1. Each time, only the liquid droplet 5 containing the light-emitting element 4 in one pixel group 1 is driven to move, so that the light-emitting element 4 is assembled into the assembly groove 21. And then the liquid droplet 5 containing the light-emitting element 4 in the next pixel group 1 is driven to move for assembly, and so on, until all the light-emitting elements 4 in all pixel groups 1 are assembled. As long as the liquid droplets 5 containing light-emitting elements 4 in two adjacent pixel groups 1 that share the second microfluidic pixel 3 are not driven to simultaneously move in the same time period, interference may be avoided, which may be designed as needed and may not be limited in the present disclosure.

In some embodiments, as illustrated in FIG. 18, the light-emitting element 4 is a light-emitting diode, the light-emitting diode includes a body part 41 and a protruding part 42 protruding from the body part 41. A width of the protruding part 42 is less than that of the assembly groove 21, and a width of the body part 41 is greater than that of the assembly groove 21. After assembling the light-emitting element 4 into the assembly groove 21, the protruding part 42 is inserted into the assembly groove 21, and the body part 41 protrudes from the assembly groove 21. The width of the protruding part 42 of the light-emitting element 4 is set to be less than that of the assembly groove 21, and the width of the body part 41 is set to be greater than that of the assembly groove 21. Therefore, the protruding part 42 may be matched with the assembly groove 21, and the assembly of the light-emitting element 4 in the assembly groove 21 may be achieved by inserting the protruding part 42 into the assembly groove 21, which is more conducive to improving the assembly efficiency. After assembling the protruding part 42 into the assembly groove 21, the light-emitting element 4 is not easily detached from the assembly groove 21, which is conducive to improving the assembly yield. In some embodiments, the light-emitting element 4 may not include the protruding part 42, but only include the body part 41. The body part 41 of the light-emitting element 4 may be directly assembled into the assembly groove 21 of the first microfluidic pixel 2. Alternatively, the light-emitting element 4 may be a micro light-emitting diode, which may be designed according to needs

At block S4, the method for transferring the light-emitting elements 4 may include attaching the microfluidic transfer substrate 100 to a driving backplane 700, so that the light-emitting elements 4 in the assembly grooves 21 are transferred onto the driving backplane 700.

In some embodiments, the driving backplane 700 is provided. As illustrated in FIG. 19, the microfluidic transfer substrate 100, which has been assembled with the light-emitting elements 4 after the operation S3, is attached to the driving backplane 700. In some embodiments, the microfluidic transfer substrate 100 is pressed onto the side of the driving backplane 700 with the driving electrodes 701, so that the light-emitting elements 4 in the assembly grooves 21 of the microfluidic transfer substrate 100 are transferred to the driving backplane 700, completing the transfer of the light-emitting elements 4. Then, the microfluidic transfer substrate 100 is separated from the driving backplane 700 for subsequent reuse of the microfluidic transfer substrate 100.

By the method for transferring the light-emitting elements 4 in the present embodiment, mass transfer of the light-emitting elements 4 may be achieved, solving the problem of difficulty in achieving mass transfer of the light-emitting elements 4 in the related art. Furthermore, the structure of the microfluidic transfer substrate 100 may increase the pixel density, thereby improving the light-emitting efficiency of the driving backplane 700.

As illustrated in FIG. 20, FIG. 20 is a flowchart of a second embodiment of the method for transferring light-emitting elements in the present disclosure.

As illustrated in FIG. 20, the present disclosure further provides another method for transferring the light-emitting elements 4, which is configured to achieve mass transfer of the light-emitting elements 4. The method for transferring the light-emitting elements 4 includes the following operations.

At block S1A, the method for transferring the light-emitting elements 4 may include providing the microfluidic transfer substrate 100.

In some embodiments, the microfluidic transfer substrate 100 is provided, which may be the microfluidic transfer substrate 100 as described in any one of above embodiments. Two adjacent pixel groups 1 share at least one second microfluidic pixel 3.

At block S2A, the method for transferring the light-emitting elements 4 may include transporting the liquid droplets 5 containing the light-emitting elements 4 to the area where a first group of pixel groups 1 is located, and driving the liquid droplets 5 containing the light-emitting elements 4 to rotate around the center points Q in the first time period, so as to assemble the light-emitting elements 4 into the assembly grooves 21; wherein two adjacent pixel groups 1 in the first group of pixel groups 1 do not share the second microfluidic pixel 3.

In some embodiments, the multiple pixel groups 1 of the microfluidic transfer substrate 100 may be distributed in an array or randomly distributed. In some embodiments, the multiple pixel groups 1 may be discretely distributed. In the first time period, the liquid droplets 5 containing the light-emitting elements 4 are transported to the area where the first group of pixel groups 1 is located. The two adjacent pixel groups 1 in the first group of pixel groups 1 do not share the second microfluidic pixel 3. That is, all pixel groups 1 in the first group of pixel groups 1 do not share the second microfluidic pixel 3 and are independent of each other.

In some embodiments, the liquid droplets 5 containing the light-emitting elements 4 that are generated in the liquid droplet generation area Y of the microfluidic transfer substrate 100 may be transported to the first group of pixel groups 1 in the transfer area Z. In some embodiments, the liquid droplet generation area Y generates and transports the liquid droplets 5 containing the light-emitting elements 4 to the area where the first group of pixel groups 1 in the transfer area Z is located through the second pixel units 6 in the liquid droplet generation area Y. Alternatively, the microfluidic transfer substrate 100 may not include the liquid droplet generation area Y. The specific structural component, such as the print head, may be disposed to directly transport the liquid droplets 5 containing the light-emitting elements 4 to the area where the first group of pixel groups 1 is located. In some embodiments, the structural component may be located above the microfluidic transfer substrate 100 and may move between areas corresponding to different pixel groups 1, so that the liquid droplets 5 containing the light-emitting elements 4 are directly dropped onto the area where the first group of pixel groups 1 of the microfluidic transfer substrate 100 is located, so that each pixel group 1 in the first group of pixel groups 1 has the liquid droplet 5 containing the light-emitting element 4.

At the same time, in the first time period, the liquid droplet 5 containing the light-emitting element 4 in each pixel group 1 in the first group of pixel groups 1 is driven to rotate around the center point Q of this pixel group 1. Therefore, the light-emitting element 4 of each pixel group 1 in the first group of pixel groups 1 is assembled into the corresponding assembly groove 21, thereby completing the assembly of the light-emitting element 4 of each pixel group 1 in the first group of pixel groups 1.

That is, in the first time period, the transport of the liquid droplets 5 containing the light-emitting elements 4 and the assembly of the light-emitting elements 4 of all pixel groups 1 in the first group of pixel groups 1 that do not share the second microfluidic pixel 3 may be completed.

At block S3A, the method for transferring the light-emitting elements 4 may include transporting the liquid droplets 5 containing the light-emitting elements 4 to the area where a second group of pixel groups 1 is located, and driving the liquid droplets 5 containing the light-emitting elements 4 to rotate around the center points Q in the second time period, so as to assemble the light-emitting elements 4 into the assembly grooves 21; wherein the adjacent pixel groups 1 in the second group of pixel groups 1 do not share the second microfluidic pixel 3; and the pixel groups 1 in the second group of pixel groups 1 correspond one-to-one with the pixel groups 1 in the first group of pixel groups 1, the pixel groups 1 in the second group of pixel groups 1 are adjacent to the pixel groups 1 in the first group of pixel groups 1, and the pixel groups 1 in the second group of pixel groups 1 and the pixel groups 1 in the first group of pixel groups 1 share at least one second microfluidic pixel 3; and the first time period and the second time period are different time periods.

In some embodiments, in the second time period, the liquid droplets 5 containing the light-emitting elements 4 are transported to the area where the second group of pixel groups 1 is located. Adjacent pixel groups 1 in the second group of pixel groups 1 do not share the second microfluidic pixel 3. The pixel groups 1 in the second group of pixel groups 1 correspond one-to-one with the pixel groups 1 in the first group of pixel groups 1. The pixel groups 1 in the second group of pixel groups 1 are adjacent to the pixel groups 1 in the first group of pixel groups 1. The pixel groups 1 in the second group of pixel groups 1 and the pixel groups 1 in the first group of pixel groups 1 share at least one second microfluidic pixel 3. The first time period and the second time period are different time periods. There is a chronological order and there is no intersection between the first time period and the second time period. Similarly, the mode of transporting the liquid droplets 5 containing the light-emitting elements 4 to the area where the second group of pixel groups 1 is located, may be the same as, the mode of transporting the liquid droplets 5 containing the light-emitting elements 4 to the area where the first group of pixel groups 1 is located, which may not be repeated here.

At the same time, in the second time period, the liquid droplet 5 containing the light-emitting element 4 in each pixel group 1 in the second group of pixel groups 1 is driven to rotate around the center point Q of this pixel group 1. Therefore, the light-emitting element 4 of each pixel group 1 in the second group of pixel groups 1 is assembled into the corresponding assembly groove 21, thereby completing the assembly of the light-emitting element 4 of each pixel group 1 in the second group of pixel groups 1.

That is, in the first time period, the transport of the liquid droplets 5 containing the light-emitting elements 4 and the assembly of the light-emitting elements 4 of all pixel groups 1 in the first group of pixel groups 1 that do not share the second microfluidic pixel 3 may be completed. In the second time period, the transport of the liquid droplets 5 containing the light-emitting elements 4 and the assembly of the light-emitting elements 4 of all pixel groups 1 in the second group of pixel groups 1 that do not share the second microfluidic pixel 3 may be completed. The pixel groups 1 in the second group of pixel groups 1 correspond one-to-one with the pixel groups 1 in the first group of pixel groups 1. The pixel groups 1 in the second group of pixel groups 1 are adjacent to the pixel groups 1 in the first group of pixel groups 1. The pixel groups 1 in the second group of pixel groups 1 and the pixel groups 1 in the first group of pixel groups 1 share at least one second microfluidic pixel 3.

In some embodiments, adjacent pixel groups 1 in the first group of pixel groups 1 do not share the second microfluidic pixel 3, adjacent pixel groups 1 in the second group of pixel groups 1 do not share the second microfluidic pixel 3. The pixel groups 1 in the second group of pixel groups 1 correspond one-to-one with the pixel groups 1 in the first group of pixel groups 1. The pixel groups 1 in the second group of pixel groups 1 are adjacent to the pixel groups 1 in the first group of pixel groups 1. The pixel groups 1 in the second group of pixel groups 1 and the pixel groups 1 in the first group of pixel groups 1 share at least one second microfluidic pixel 3. By completing the transport of the liquid droplets 5 containing the light-emitting elements 4 and the assembly of the light-emitting elements 4 in the first group of pixel groups 1, and the transport of the liquid droplets 5 containing the light-emitting elements 4 and the assembly of the light-emitting elements 4 in the second group of pixel groups 1 at two different time periods, there may be no interference in the transport, movement, and assembly process of the liquid droplets 5 containing the light-emitting elements 4 in the first group of pixel groups 1 and the second group of pixel groups 1. It may ensure the smooth assembly of the light-emitting element 4 into the corresponding assembly groove 21, thereby improving the assembly accuracy and the assembly yield. For the multiple pixel groups 1 of the same type (such as all pixel groups 1 in the first group of pixel groups 1 or all pixel groups 1 in the second group of pixel groups 1), the liquid droplets 5 containing the light-emitting elements 4 are uniformly transported and the light-emitting elements 4 are uniformly assembled, which may further improve the assembly efficiency.

At block S4A, the method for transferring the light-emitting elements 4 may include attaching the microfluidic transfer substrate 100 to the driving backplane 700, so that the light-emitting elements 4 in the assembly grooves 21 are transferred to the driving backplane 700.

In some embodiments, the operation S4A in the method for transferring the light-emitting elements 4 in the second embodiment is the same as the operation S4 in the method for transferring the light-emitting elements 4 in the first embodiment, and they may achieve the same or similar technical effects, which may not be repeated here.

By the method for transferring the light-emitting elements 4 in some embodiments, the mass transfer of the light-emitting elements 4 may be achieved, which may solve the problem that it is difficult to achieve mass transfer of the light-emitting elements 4 in related art. Furthermore, the structure of the microfluidic transfer substrate 100 may increase the pixel density, thereby improving the light-emitting efficiency of the driving backplane 700.

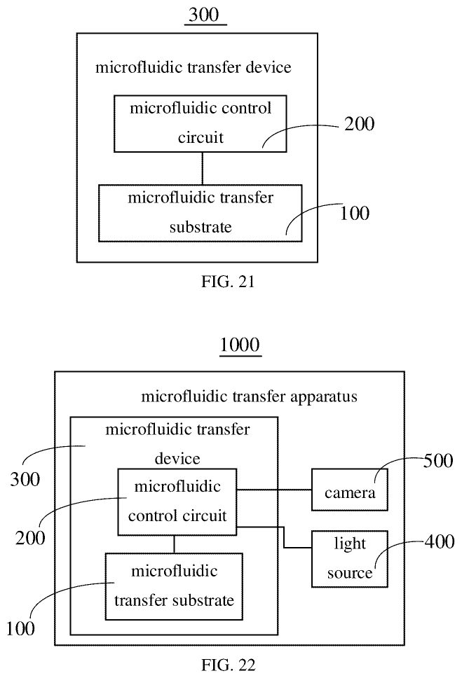

As illustrated in FIG. 21, FIG. 21 is a structural block view of a microfluidic transfer device in the present disclosure.

As illustrated in FIG. 21, the present disclosure further provides a microfluidic transfer device 300. The microfluidic transfer device 300 includes the microfluidic transfer substrate 100 of any one of above embodiments and a microfluidic control circuit 200. The microfluidic control circuit 200 is electrically connected to the microfluidic transfer substrate 100. The microfluidic control circuit 200 may be configured to drive the first pixel units 11 of the pixel group 1, so that the liquid droplets 5 containing the light-emitting elements 4 are driven to swing back and forth between the first microfluidic pixel 2 and the second microfluidic pixels 3 of the pixel group 1 or rotate around the center point Q, so as to assemble the light-emitting elements 4 into the assembly grooves 21.

As illustrated in FIG. 22, FIG. 22 is a structural block view of a microfluidic transfer apparatus in the present disclosure.

As illustrated in FIG. 22, the present disclosure further provides a microfluidic transfer apparatus 1000. The microfluidic transfer apparatus 1000 includes the microfluidic transfer device 300, a light source 400, and a camera 500. The light source 400 is disposed on one side of the microfluidic transfer substrate 100 of the microfluidic transfer device 300 and electrically connected to the microfluidic control circuit 200. The camera 500 is disposed on the other side of the microfluidic transfer substrate 100 and electrically connected to the microfluidic control circuit 200. The microfluidic control circuit 200 is further configured to control the light source 400 to emit light and irradiate the microfluidic transfer substrate 100, control the camera 500 to capture an image of the microfluidic transfer substrate 100, and determine whether the light-emitting element 4 is assembled in the assembly groove 21 based on the image captured by the camera 500. Therefore, the first microfluidic pixel 2 that is not assembled with the light-emitting element 4 may be screened out for subsequent operations, such as secondary assembly.

Different from the related art, the effects of the present disclosure are as follows. The microfluidic transfer substrate includes a plurality of pixel groups. Each pixel group includes at least three first pixel units, and the at least three first pixel units of each pixel group are arranged around a center point; and one first pixel unit of each pixel group serves as a first microfluidic pixel and a surface of the first microfluidic pixel defines an assembly groove, and the other first pixel units of each pixel group serve as second microfluidic pixels and a surface of each second microfluidic pixel is free of the assembly groove. Two adjacent pixel groups share at least one second microfluidic pixel. In the above-mentioned microfluidic transfer substrate, at least one second microfluidic pixel may be shared by two adjacent pixel groups, which may achieve mass transfer of the light-emitting elements and increase the pixel density of the microfluidic transfer substrate, thereby improving the light-emitting efficiency of the light-emitting elements transferred to the driving backplane.

The above descriptions are only some embodiments of the present disclosure, and are not intended to limit the protection scope of the present disclosure. Any equivalent structure or equivalent flow transformation made by using the contents and the accompanying drawings of the present disclosure, or directly or indirectly applied to other related technical fields, is included in the protection scope of the present disclosure.

1. A microfluidic transfer substrate, comprising:
a plurality of pixel groups, wherein each pixel group comprises at least three first pixel units, and the at least three first pixel units of each pixel group are arranged around a center point; and one first pixel unit of each pixel group serves as a first microfluidic pixel and a surface of the first microfluidic pixel defines an assembly groove, and the other first pixel units of each pixel group serve as second microfluidic pixels and a surface of each second microfluidic pixel is free of the assembly groove;
wherein two adjacent pixel groups share at least one second microfluidic pixel.

2. The microfluidic transfer substrate according to claim 1, wherein
the plurality of pixel groups are arranged in a two-dimensional array; each pixel group comprises four first pixel units, and the four first pixel units of the same pixel group are arranged to form a two-dimensional array with two rows and two columns; and two adjacent pixel groups in the same row share two second microfluidic pixels.

3. The microfluidic transfer substrate according to claim 2, wherein
two adjacent pixel groups in the same row share two second microfluidic pixels, and two adjacent pixel groups in the same column share two second microfluidic pixels.

4. The microfluidic transfer substrate according to claim 1, wherein
nine first pixel units arranged in three rows and three columns form a repeating unit, four first pixel units located at four corners of each repeating unit are the first microfluidic pixels, and the other five first pixel units are the second microfluidic pixels.

5. The microfluidic transfer substrate according to claim 1, wherein
each first pixel unit comprises a substrate, a thin film transistor, a first insulation layer, a planarization layer, a microfluidic electrode layer, a second insulation layer, and a hydrophobic layer arranged in sequence; and the planarization layer defines a through hole to expose a part of the first insulation layer, so that the assembly groove is formed; and
the microfluidic electrode layer, the second insulation layer, and the hydrophobic layer all cover a bottom surface and a side surface of the assembly groove; or, the microfluidic electrode layer is only disposed on a surface of the planarization layer away from the substrate and defines an opening corresponding to the assembly groove, and the second insulation layer and the hydrophobic layer both cover the bottom surface and the side surface of the assembly groove.

6. The microfluidic transfer substrate according to claim 5, wherein
the microfluidic transfer substrate comprises a transfer area and a liquid droplet generation area surrounding the transfer area; the plurality of pixel groups are disposed in the transfer area, and the liquid droplet generation area is configured to generate and transport a liquid droplet containing a light-emitting element to the transfer area; and a plurality of second pixel units are disposed in the liquid droplet generation area, and a structure of each second pixel unit is the same as that of each second microfluidic pixel.

7. A method for transferring light-emitting elements, comprising:
providing a microfluidic transfer substrate comprising:
a plurality of pixel groups, wherein each pixel group comprises at least three first pixel units, and the at least three first pixel units of each pixel group are arranged around a center point; and one first pixel unit of each pixel group serves as a first microfluidic pixel and a surface of the first microfluidic pixel defines an assembly groove, and the other first pixel units of each pixel group serve as second microfluidic pixels and a surface of each second microfluidic pixel is free of the assembly groove; and two adjacent pixel groups share at least one second microfluidic pixel;
forming a liquid droplet containing a light-emitting element in an area where each pixel group of the microfluidic transfer substrate is located, wherein at most one of two liquid droplets containing the light-emitting elements in areas where two adjacent pixel groups are located is located on the shared second microfluidic pixel;
driving the two liquid droplets containing the light-emitting elements in the areas where the two adjacent pixel groups are located in a time-sequenced manner, so that the two liquid droplets containing the light-emitting elements rotate around the center points at different time periods, so as to assemble the light-emitting elements into the assembly grooves; and
attaching the microfluidic transfer substrate to a driving backplane, so that the light-emitting elements in the assembly grooves are transferred to the driving backplane.

8. The method for transferring light-emitting elements according to claim 7, wherein
the plurality of pixel groups are arranged in a two-dimensional array; each pixel group comprises four first pixel units, and the four first pixel units of the same pixel group are arranged to form a two-dimensional array with two rows and two columns; and two adjacent pixel groups in the same row share two second microfluidic pixels.

9. The method for transferring light-emitting elements according to claim 8, wherein
two adjacent pixel groups in the same row share two second microfluidic pixels, and two adjacent pixel groups in the same column share two second microfluidic pixels.

10. The method for transferring light-emitting elements according to claim 7, wherein
nine first pixel units arranged in three rows and three columns form a repeating unit, four first pixel units located at four corners of each repeating unit are the first microfluidic pixels, and the other five first pixel units are the second microfluidic pixels.

11. The method for transferring light-emitting elements according to claim 7, wherein
each first pixel unit comprises a substrate, a thin film transistor, a first insulation layer, a planarization layer, a microfluidic electrode layer, a second insulation layer, and a hydrophobic layer arranged in sequence; and the planarization layer defines a through hole to expose a part of the first insulation layer, so that the assembly groove is formed; and
the microfluidic electrode layer, the second insulation layer, and the hydrophobic layer all cover a bottom surface and a side surface of the assembly groove; or, the microfluidic electrode layer is only disposed on a surface of the planarization layer away from the substrate and defines an opening corresponding to the assembly groove, and the second insulation layer and the hydrophobic layer both cover the bottom surface and the side surface of the assembly groove.

12. The method for transferring light-emitting elements according to claim 11, wherein
the microfluidic transfer substrate comprises a transfer area and a liquid droplet generation area surrounding the transfer area; the plurality of pixel groups are disposed in the transfer area, and the liquid droplet generation area is configured to generate and transport a liquid droplet containing a light-emitting element to the transfer area; and a plurality of second pixel units are disposed in the liquid droplet generation area, and a structure of each second pixel unit is the same as that of each second microfluidic pixel.

13. A method for transferring light-emitting elements, comprising:
providing a microfluidic transfer substrate comprising:
a plurality of pixel groups, wherein each pixel group comprises at least three first pixel units, and the at least three first pixel units of each pixel group are arranged around a center point; and one first pixel unit of each pixel group serves as a first microfluidic pixel and a surface of the first microfluidic pixel defines an assembly groove, and the other first pixel units of each pixel group serve as second microfluidic pixels and a surface of each second microfluidic pixel is free of the assembly groove; and two adjacent pixel groups share at least one second microfluidic pixel;
transporting the liquid droplets containing the light-emitting elements to an area where a first group of pixel groups is located, and driving the liquid droplets containing the light-emitting elements to rotate around the center points, so as to assemble the light-emitting elements into the assembly grooves in a first time period; wherein adjacent pixel groups in the first group of pixel groups do not share the second microfluidic pixel;
transporting the liquid droplets containing the light-emitting elements to an area where a second group of pixel groups is located, and driving the liquid droplets containing the light-emitting element to rotate around the center points, so as to assemble the light-emitting elements into the assembly grooves in a second time period; wherein adjacent pixel groups in the second group of pixel groups do not share the second microfluidic pixel; the pixel groups in the second group of pixel groups correspond one-to-one with the pixel groups in the first group of pixel groups, the pixel groups in the second group of pixel groups are adjacent to the pixel groups in the first group of pixel groups, and the pixel groups in the second group of pixel groups and the pixel groups in the first group of pixel groups share at least one second microfluidic pixel; and the first time period and the second time period are different time periods; and
attaching the microfluidic transfer substrate to a driving backplane, so that the light-emitting elements in the assembly grooves are transferred to the driving backplane.

14. The method for transferring light-emitting elements according to claim 13, wherein
the plurality of pixel groups are arranged in a two-dimensional array; each pixel group comprises four first pixel units, and the four first pixel units of the same pixel group are arranged to form a two-dimensional array with two rows and two columns; and two adjacent pixel groups in the same row share two second microfluidic pixels.

15. The method for transferring light-emitting elements according to claim 14, wherein
two adjacent pixel groups in the same row share two second microfluidic pixels, and two adjacent pixel groups in the same column share two second microfluidic pixels.

16. The method for transferring light-emitting elements according to claim 13, wherein
nine first pixel units arranged in three rows and three columns form a repeating unit, four first pixel units located at four corners of each repeating unit are the first microfluidic pixels, and the other five first pixel units are the second microfluidic pixels.

17. The method for transferring light-emitting elements according to claim 13, wherein
each first pixel unit comprises a substrate, a thin film transistor, a first insulation layer, a planarization layer, a microfluidic electrode layer, a second insulation layer, and a hydrophobic layer arranged in sequence; and the planarization layer defines a through hole to expose a part of the first insulation layer, so that the assembly groove is formed; and
the microfluidic electrode layer, the second insulation layer, and the hydrophobic layer all cover a bottom surface and a side surface of the assembly groove; or, the microfluidic electrode layer is only disposed on a surface of the planarization layer away from the substrate and defines an opening corresponding to the assembly groove, and the second insulation layer and the hydrophobic layer both cover the bottom surface and the side surface of the assembly groove.

18. The method for transferring light-emitting elements according to claim 17, wherein
the microfluidic transfer substrate comprises a transfer area and a liquid droplet generation area surrounding the transfer area; the plurality of pixel groups are disposed in the transfer area, and the liquid droplet generation area is configured to generate and transport a liquid droplet containing a light-emitting element to the transfer area; and a plurality of second pixel units are disposed in the liquid droplet generation area, and a structure of each second pixel unit is the same as that of each second microfluidic pixel.
